(19) United States
(12) Patent Application Publication
(10) Pub. No.: US 2023/0411554 A1
(43) Pub. Date: Dec. 21, 2023

(54) SMALL SIZE LIGHT EMITING DIODES FABRICATED VIA REGROWTH

(71) Applicant: THE REGENTS OF THE UNIVERSITY OF CALIFORNIA, OAKLAND, CA (US)

(72) Inventors: Srinivas Gandrothula, Ibaraki (JP); Takeshi Kamikawa, Kyoto (JP)

(73) Assignee: THE REGENTS OF THE UNIVERSITY OF CALIFORNIA, OAKLAND, CA (US)

(21) Appl. No.: 18/248,623

(22) PCT Filed: Oct. 22, 2021
(86) PCT No.: PCT/US21/56154

§ 371 Date: Apr. 12, 2023

Related U.S. Application Data
(60) Provisional application No. 63/104,580, filed on Oct. 23, 2020.

(51) Int. Cl. H01L 33/00; H01L 25/075

(52) U.S. Cl. CPC H01L 33/0075; H01L 33/0093; H01L 25/0753

(57) ABSTRACT

A method for fabricating and transferring high quality and manufacturable light-emitting devices, such as small sized light-emitting diodes (mLEDs), using epitaxial lateral overgrowth (ELO) and isolation methods. III-nitride ELO layers are grown on a host substrate using a growth restrict mask, and III-nitride device layers are grown on wings of the III-nitride ELO layers. The resulting devices are isolated from the host substrate while attached by a connecting link comprising an epitaxial or non-epitaxial bridge. A regrowth is performed on selected mesas of the device layers to realize improved devices with the help of the bridge. The bridge is broken, and the devices are then plucked from the host substrate and placed on a display panel.

### CROSS REFERENCE TO RELATED APPLICATIONS

This application claims the benefit under 35 U.S.C. Section 119(e) of the following co-pending and commonly-assigned application:

U.S. Provisional Application Ser. No. 63/104,580, filed on Oct. 23, 2020, by Srinivas Gandrothula and Takeshi Kamikawa, entitled “SMALL SIZE LIGHT EMITING DIODES FABRICATED VIA REGROWTH,” attorneys' docket number G&C 30794.0784USP1 (UC 2020-561-1);
which application is incorporated by reference herein.

This application is related to the following co-pending and commonly-assigned applications:

U.S. Utility patent application Ser. No. 16/608,071, filed on Oct. 24, 2019, by Takeshi Kamikawa, Srinivas Gandrothula, Hongjian Li and Daniel A. Cohen, entitled “METHOD OF REMOVING A SUBSTRATE,” attorney's docket no. 30794.0653USWO (UC 2017-621-2), which application claims the benefit under 35 U.S.C. Section 365(c) of co-pending and commonly-assigned PCT International Patent Application Serial No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” attorney's docket no. 30794.0653USWO (UC 2017-621-2), which application claims the benefit under 35 U.S.C. Section 119(e) of co-pending and commonly-assigned U.S. Provisional Patent Application Ser. No. 62/502,205, filed on May 5, 2017, by Takeshi Kamikawa, Srinivas Gandrothula, Hongjian Li and Daniel A. Cohen, entitled “METHOD OF REMOVING A SUBSTRATE,” attorney's docket no. 30794.0653USP1 (UC 2017-621-1);

U.S. Utility patent application Ser. No. 16/642,298, filed on Feb. 26, 2020, by Takeshi Kamikawa, Srinivas Gandrothula and Hongjian Li, entitled “METHOD OF REMOVING A SUBSTRATE WITH A CLEAVING TECHNIQUE,” attorney's docket no. 30794.0659USWO (UC 2018-086-2), which application claims the benefit under 35 U.S.C. Section 365(c) of co-pending and commonly-assigned PCT International Patent Application Serial No. PCT/US18/51375, filed on Sep. 17, 2018, by Takeshi Kamikawa, Srinivas Gandrothula and Hongjian Li, entitled “METHOD OF REMOVING A SUBSTRATE WITH A CLEAVING TECHNIQUE,” attorney's docket no. 30794.0659WOU1 (UC 2018-086-2), which application claims the benefit under 35 U.S.C. Section 119(e) of co-pending and commonly-assigned U.S. Provisional Patent Application Ser. No. 62/559,378, filed on Sep. 15, 2017; by Takeshi Kamikawa, Srinivas Gandrothula and Hongjian Li, entitled “METHOD OF REMOVING A SUBSTRATE WITH A CLEAVING TECHNIQUE,” attorney's docket no. 30794.0659USP1 (UC 2018-086-1);

U.S. Utility patent application Ser. No. 16/978,493, filed on Sep. 4, 2020, by Takeshi Kamikawa, Srinivas Gandrothula and Hongjian Li, entitled “METHOD OF FABRICATING NON-POLAR AND SEMI-POLAR DEVICES USING EPITAXIAL LATERAL OVERGROWTH,” attorney's docket no. 30794.0680USWO (UC 2018-427-2), which application claims the benefit under 35 U.S.C. Section 365(c) of co-pending and commonly-assigned PCT International Patent Application Serial No. PCT/US19/25187, filed on Apr. 1, 2019, by Takeshi Kamikawa, Srinivas Gandrothula and Hongjian Li, entitled “METHOD OF FABRICATING NON-POLAR AND SEMI-POLAR DEVICES USING EPITAXIAL LATERAL OVERGROWTH,” attorney's docket no. 30794.0680WOU1 (UC 2018-427-2), which application claims the benefit under 35 U.S.C. Section 119(e) of co-pending and commonly-assigned U.S. Provisional Patent Application Ser. No. 62/650,487, filed on Mar. 30, 2018, by Takeshi Kamikawa, Srinivas Gandrothula, and Hongjian Li, entitled “METHOD OF FABRICATING NON-POLAR AND SEMI-POLAR DEVICES USING EPITAXIAL LATERAL OVERGROWTH,” attorney docket number G&C 30794.0680USP1 (UC 2018-427-1);

U.S. Utility patent application Ser. No. 17/048,383, filed on Oct. 16, 2020, by Takeshi Kamikawa and Srinivas Gandrothula, entitled “METHOD FOR DIVIDING A BAR OF ONE OR MORE DEVICES,” attorney's docket no. 30794.0681USWO (UC 2018-605-2), which application claims the benefit under 35 U.S.C. Section 365(c) of co-pending and commonly-assigned PCT International Patent Application Serial No. PCT/US19/32936, filed on May 17, 2019, by Takeshi Kamikawa and Srinivas Gandrothula, entitled “METHOD FOR DIVIDING A BAR OF ONE OR MORE DEVICES,” attorney's docket no. 30794.0681WOU1 (UC 2018-605-2), which application claims the benefit under 35 U.S.C. Section 119(e) of co-pending and commonly-assigned U.S. Provisional Application Ser. No. 62/672,913, filed on May 17, 2018, by Takeshi Kamikawa and Srinivas Gandrothula, entitled “METHOD FOR DIVIDING A BAR OF ONE OR MORE DEVICES,” attorneys' docket number G&C 30794.0681USP1 (UC 2018-605-1); and

U.S. Utility patent application Ser. No. 17/049,156, filed on Oct. 20, 2020, by Srinivas Gandrothula and Takeshi Kamikawa, entitled “METHOD OF REMOVING SEMICONDUCTING LAYERS FROM A SEMICONDUCTING SUBSTRATE,” attorney's docket no. 30794.0682USWO (UC 2018-614-2), which application claims the benefit under 35 U.S.C. Section 365(c) of co-pending and commonly-assigned PCT International Patent Application Serial No. PCT/US19/34868, filed on May 30.2019, by Srinivas Gandrothula and Takeshi Kamikawa, entitled “METHOD OF REMOVING SEMICONDUCTING LAYERS FROM A SEMICONDUCTING SUBSTRATE,” attorneys' docket number G&C 30794.0682WOU1 (UC 2018-614-2), which application claims the benefit under 35 U.S.C. Section 119(e) of co-pending and commonly-assigned U.S. Provisional Application Ser. No. 62/677,833, filed on May 30, 2018, by Srinivas Gandrothula and Takeshi Kamikawa, entitled “METHOD OF REMOVING SEMICONDUCTING LAYERS FROM A SEMICONDUCTING SUBSTRATE,” attorneys' docket number G&C 30794.0682USP1 (UC 2018-614-1);
all of which applications are incorporated by reference herein.

### BACKGROUND OF THE INVENTION

### 1. Field of the Invention

This invention is directed to small size light emitting diodes (LEDs) fabricated via regrowth.

### 2. Description of the Related Art

Micro-displays based on an array of micro-sized light emitting diodes (μLEDs) are a promising technology for a wide range of applications. μLEDs are inorganic LEDs in micron dimensions and are self-emissive, which means μLEDs can attain the highest contrast ratio and simplify display panel design.

Recently, there has been some research interests in employing μLEDs in sizes from 100 to 200 μm as the backlight source in Liquid Crystal Displays (LCDs) to boost the contrast ratio, to reduce the complexity of LCD architecture, and to improve other display parameters, such as viewing angle and aperture ratio.

Since μLEDs are sized in the microscopic scale, each μLED represents a pixel in monochromic displays or three red, green, and blue μLEDs form a pixel in full-color displays. In addition, μLEDs are comprised of mature inorganic semiconductor materials, such as InGaN or AlGaInP, that provide advantages superior than existing display technologies such as LCDs and organic-LEDs, including high peak brightness, remarkable energy efficiency, chemical robustness, and long operating lifespan.

In 2-dimensional arrays, each μLED works as a single pixel of a whole image. These micro-displays can be used in applications ranging from TVs, laptops, smartphones, heads-up displays (HUDs) and augmented reality/virtual reality/mixed reality (AR/VR/MR) applications.

One present focus is μLEDs of the III-nitride material system, which consists of the chemical formula GaₓAl_{y}In_{z}N where 0≤x≤1, 0≤y≤1, 0≤z≤1, and x+y+z=1. The majority of research attention focuses on InGaN-based μLEDs, although there is some research on UV-A AlGaN μLEDs for display applications.

One of the most vital advantages of the III-nitride material system is emission wavelength tunability by varying the composition percentage of indium and gallium in the active region, also known as the quantum wells, since the bandgaps of GaN and InN are 3.4 eV and 0.7 eV, respectively, and the alloy of InGaN system can theoretically cover the entire visible spectrum.

Unfortunately, III-nitride based LEDs become inefficient as device dimensions shrink due to nonradiative recombination losses at exposed surfaces. These losses originate from nonradiative surface states, such as point defects and dangling bonds for Gallium (Ga) atoms, which are largely introduced during plasma-based device patterning. Due to high surface-area-to-volume ratios, these effects become ever more important for micro-LEDs. Analysis of external quantum efficiency (EQE) curves suggested that the Shockley-Read-Hall (SRH) recombination rate rose by over an order of magnitude when device dimensions dropped.

Although III-nitride μLEDs have great potential in display and other emerging applications, there are some challenges needed to be addressed before the realization of commercial products for mass production. Three essential issues of III-nitride μLEDs are: size-dependent efficiency, color gamut (long-wavelength emission), and mass-transfer techniques. The present invention addresses these issues.

### SUMMARY OF THE INVENTION

To overcome the limitations in the prior art described above, and to overcome other limitations that will become apparent upon reading and understanding this specification, the present invention discloses a method for fabricating semiconducting layer(s) on a host substrate, where the host substrate can be a homogeneous or foreign substrate, or a template containing materials of separated semiconducting layers, and then separating the semiconducting layer(s) from the host substrate. The separation is performed at a wing of III-nitride layers grown by epitaxial lateral overgrowth (ELO), thereby resulting in a device on these layers that has good crystal quality in terms of reduced dislocation densities and stacking faults.

Specifically, this invention performs the following steps: island-like III-nitride semiconductor layers are grown on a substrate using a growth restrict mask and the ELO method. The ELO regions are meant to be regions with reduced dislocation densities, as compared to regions that are not ELO regions. A light emitting aperture of the light emitting region of the micro-LED is confined to the wings of the ELO region, at least in part, where good crystal quality layers can be guaranteed.

The following device realization can be performed in two ways. In one method, an epitaxial bridge is constructed when the ELO layers include a p-type layer. In such a scenario, some care must be taken in the reintroduced crystalline growth chamber temperatures as higher temperatures may damage or degrade the previously grown active region's quantum well layers. Pulsed laser deposition techniques may be used to deposit a p-type layer, or alternatively, molecular beam epitaxy (MBE) equipment can be used as a regrowth crystalline layer chamber, where growth temperatures are not as aggressive as metal oxide vapor phase epitaxy (MOVPE) or metal oxide chemical vapor deposition (MOCVD), etc.

In another method, an epitaxial bridge is formed after completion of n-type ELO layers. As carrier activation energy in n-type layers is smaller compared to activation energy of carriers from p-type layers, the damage to n-type layers when exposed to plasma etching may not be as severe as p-type layers. In this case, a mesa for regrowth layers is opened over an ELO wing, in addition to forming an epitaxial bridge. In this scenario, as regrowth is performed to fully grow device layers in addition to above mentioned regrowth chambers, much-accelerated parameters can be used to grow a fully light emitting device layers.

In both of the above scenarios, instead of an epitaxial bridge, a non-epitaxial bridge, layer which may or may not be different from growth restrict mask material, can be used to push the light aperture onto the ELO wing while holding the device layers when reintroduced into a crystalline layers regrowth chamber.

Thereafter, front-end processing is performed until the p-pad and n-pad can be finished on the ELO wing, and then device units are plucked from the host substrate. Note that the isolated device units remain on the host substrate with a very minimal link using the epitaxial or non-epitaxial bridge until the device process is finished. The devices then can be removed from the substrate either by an elastomer stamp, or a vacuum chuck, or an adhesive tape, or simply by bonding, or by attaching the devices to a separate carrier substrate.

In particular, the interface at the growth restrict mask surface and the ELO regions is sufficiently smooth. The measured roughness was on the order of <2 nm, as these layers' surface is merely a replication of the surface of the growth restrict mask for the ELO process. This smoothness may help to keep the device units on a display panel for further processing, such as electrical connection pads.

As fabricated μLEDs on the ELO wings can be transferred onto a different carrier for further processing by means of a simple stamp, or a vacuum chuck, or glue attached a carrier plate, etc. The III-nitride semiconductor layers are dimensioned such that one or more of the island-like III-nitride semiconductor layers form a bar of one or more devices. By doing this, nearly identical devices can be fabricated adjacent to each other in a self-assembled array, and thus, by integration, scale up can be made easier. Alternatively, ELO III-nitride layers can made to coalesce initially, such that they can be later divided into bars of devices or individual chips.

Every device of such a bar can be addressed separately or together with other devices, by designing a proper fabrication process. For example, one could make a common cathode or anode for such a device bar for monolithic integration, or one can address individual devices for full color display applications. Consequently, a high yield can be obtained.

The big advantages of this invention include connecting the device units with a layer above the opening area using the epitaxial and non-epitaxial bridges that allow the layers damaged by dry etching to cure the surface defects by the regrowth of the epitaxial layers.

The epitaxial or non-epitaxial bridge can avoid the contamination and the distortion of the bridge even if the bridge is exposed to high regrowth temperature circumstances. The point is to implement the regrowth for healing the damage to the layer before the removal of the growth restrict mask. The growth restrict mask can support the epitaxial bridge, which can avoid the deformation of the epitaxial bridge.

Moreover, the epitaxial or non-epitaxial bridge can position the emitting aperture away from the opening area, which has a lot of defects from the substrate's surface. This can reduce the number of the defects in the emitting aperture. To use the low defect area on the growth restrict mask can make the long wavelength device, such as a green or red light emitting device, improve its reliability efficiently.

Key aspects of this invention include:
This invention can utilize homogeneous and heterogeneous substrates, including III-nitride substrates, III-nitride templates on substrates, foreign substrates such as Si, SiC, sapphire, etc., to scale up manufacturability for industrial needs. This invention is also independent of crystal orientations of the native substrate.
This invention fabricates a light emitting area of the device on wings of the III-nitride ELO layers, thereby providing better crystal quality in the light emission area, which improves performance.
This invention can be utilized to increase yield by making smaller footprint devices confined to the wings of the III-nitride ELO layers.
A light-emitting aperture of the device is made on the wing of the III-nitride ELO layers, which provides better crystal quality in terms of reduced defects and stacking faults than a light-emitting aperture made directly on a native substrate.
An epitaxial or non-epitaxial bridge will assist to reintroduce isolated device units and layers into the crystalline layered growth environment.
Regrown crystalline layers heal the damage associated with plasma based etching experienced with the creation of mesas.
A very thin high carrier doping layer (p-type) was regrown on the reintroduced completed device layers, which may avoid the damage by reducing the time exposure of the active region in the regrowth chamber
Alternatively, n-type ELO layers with an epitaxial or non-epitaxial bridge can be reintroduced into the regrowth chamber for complete device crystalline layers growth.
No damage is generated as laser liftoff is not used to separate device layers from the substrate.
A damage-free separation process may be applied to any kind of substrate, including homogeneous and heterogeneous substrates.
The process to transfer devices is enhanced, as selected devices can be extracted from the host substrate.
A vacuum process or stamping process enables selectivity of the devices.
Wafer-to-wafer bonding problems, such as bowing, can be avoided as this invention bonds discrete or separated devices from the host substrate to an external carrier, which typically is a better thermal conducting carrier. Also, instead of attaching discrete devices together to an external carrier, which restricts the available thermal spread on the carrier, more thermal space can be allocated to each device on the carrier by selective transfer.
The substrate can be recycled for a next batch of devices.

A few of the possible designs using this method are illustrated in the following detailed description of the invention. The invention has many benefits as compared to conventionally manufacturable device elements when combined with the cross-referenced inventions on removing semiconducting devices from a semiconducting substrate set forth above.

### BRIEF DESCRIPTION OF THE DRAWINGS

Referring now to the drawings in which like reference numbers represent corresponding parts throughout:

FIG. 1 is a schematic of a substrate, growth restrict mask, non-coalesced III-nitride epitaxial lateral overgrowth (ELO) layers, and coalesced III-nitride ELO layers, according to one embodiment of the present invention.

FIGS. 2A, 2B, and 2C illustrate that III-nitride ELO layers and III-nitride device layers together form island-like III-nitride semiconductor layers, according to one embodiment of the present invention.

FIGS. 3A and 3B illustrate, irrespective of the ELO layer patterns in FIGS. 2A and 2B, III-nitride ELO device layers isolated as desired shape from the host substrate with a designated epitaxial bridge.

FIGS. 3C and 3D illustrate, irrespective of the ELO layer patterns in FIGS. 2A and 2B, III-nitride ELO device layers isolated as desired shape from the host substrate with a designated non-epitaxial link.

FIG. 4A illustrates an ELO wing with coalesced region including open region;

FIG. 4B illustrates a mesa structure formed on the device layers of ELO wing; FIG. 4C illustrates a blanket deposited passivation layer; FIG. 4D illustrates an opening of a light emitting region on a p-type layer; FIG. 4E illustrates a device mesa along with an epitaxial bridge structure formation; FIG. 4F illustrates deep etching to expose a growth restrict mask; FIG. 4G illustrates a growth restrict layer for protecting exposed epitaxial layers of the device mesa in deep etching; FIG. 4H illustrates a regrowth mesa opening on the p-layer; FIG. 4I illustrates a thin p-layer regrowth; FIG. 4J illustrates a hanging epitaxial bridge device structure; FIG. 4K illustrates a TCO layer window formation; FIG. 4L illustrates p-pad and n-pad deposition; FIG. 4M illustrates plucking of hanging epitaxial bridge device structures using a stamp and then placing them on a display panel; and FIG. 4N is a flow chart of the process to realize micro-LED display panel.

FIG. 5A illustrates an ELO wing with coalesced region including open region; FIG. 5B illustrates a device mesa structure formed on the device n-type layers of an ELO wing; FIG. 5C illustrates deep etching to isolate device units along with formation of epitaxial bridge; FIG. 5D illustrates a growth restrict layer for protecting exposed epitaxial layers of the device mesa in deep etching; FIG. 5E illustrates an opening of a regrowth patch over an n-type ELO layer wing; FIG. 5F illustrates regrown device layers including, n-type, active region, electron blocking layer, and p-type layers; FIG. 5G illustrates a TCO blanket deposition; FIG. 5H illustrates securing a light emitting portion on the device mesa; FIG. 5I illustrates etching away short circuiting paths; FIG. 5J illustrates a liftoff securing mask layer; FIG. 5K illustrates p-pad and n-pad formation; FIG. 5L illustrates plucking of hanging epitaxial bridge device structures using a stamp and then placing them on a display panel, and FIG. 5M is a flow chart of the process to realize micro-LED display panel.

FIGS. 6A, 6B and 6C illustrate a vertical pad configuration, where interface between base ELO layer and the growth restrict mask will be used as n-type current injection.

FIG. 7 is a design of a vacuum chuck to pick isolated III-nitride ELO device layers out of the host substrate.

FIG. 8 is a flowchart illustrating how to fabricate semiconducting devices according to this invention.

### DETAILED DESCRIPTION OF THE INVENTION

In the following description of the preferred embodiment, reference is made to a specific embodiment in which the invention may be practiced. It is to be understood that other embodiments may be utilized, and structural changes may be made without departing from the scope of the present invention.

Overview

The present invention describes a method of fabricating semiconductor devices, such as light emitting devices, including LEDs, wherein the semiconducting layers remain on the host substrate with a very delicate contact, known as an epitaxial bridge. As ELO is relied on, this invention is easily applicable to foreign substrates, such as Si, SiC, sapphire, templates of semiconductor layers, or a host substrate containing ELO engineered layers templates. This invention covers LEDs, micro-cavity LEDs can be fabricated on good crystal quality ELO wings, which can be isolated from the host substrate, and then can be picked selectively or can be transferred onto a display back panel.

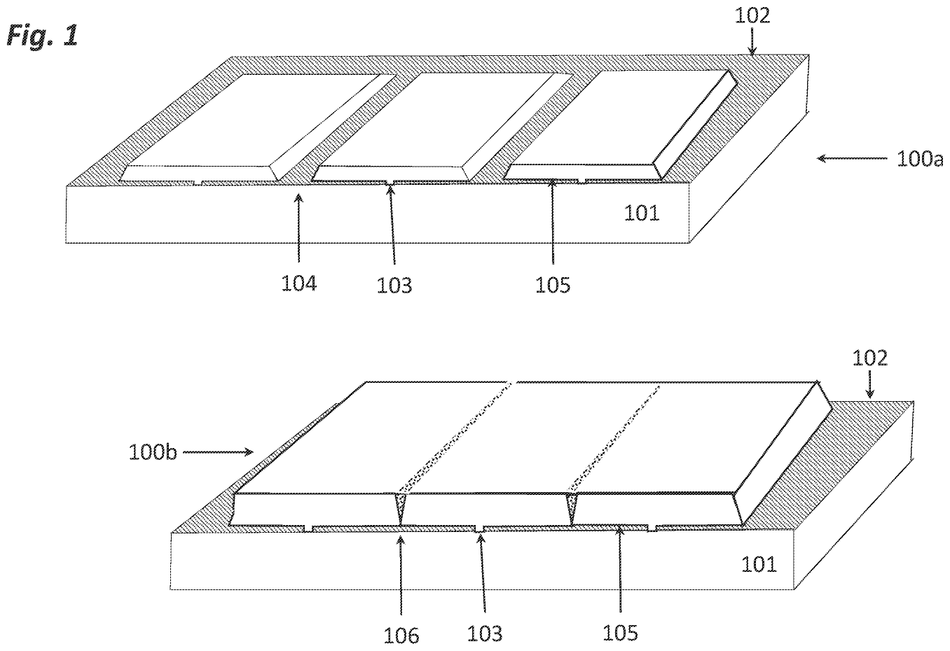

FIG. 1 illustrates a method using schematics 100A and 100B. The method first provides a III-nitride-based substrate 101, such as a bulk GaN substrate 101.

In schematic 100A, a growth restrict mask 102 is formed on or above the III-nitride based substrate 101. Specifically, the growth restrict mask 102 is disposed directly in contact with the substrate 101, or is disposed indirectly through an intermediate layer grown by MOCVD, etc., made of III-nitride-based semiconductor layer or template deposited on the substrate 101.

The growth restrict mask 102 can be formed from an insulator film, for example, an SiO₂ film deposited upon the base substrate 101, for example, by a plasma chemical vapor deposition (CVD), sputter, ion beam deposition (IBD), etc., wherein the SiO₂ film is patterned by photolithography using a predetermined photo mask and then etched to include opening areas 103, as well as no-growth regions 104 (which may or may not be patterned). The present invention can use SiO₂, SiN, SiON, TiN, etc., as the growth restrict mask 102. A multi-layer growth restrict mask 102 which is comprised of the above materials is preferred.

Epitaxial III-nitride layers 105, such as GaN-based layers, are grown using the ELO method on the GaN substrate 101 and the growth restrict mask 102. The growth of the III-nitride ELO layers 105 occurs first in the opening areas 103, on the III-nitride based substrate 101, and then laterally from the opening areas 103 over the growth restrict mask 102. The growth of the III-nitride ELO layers 105 may be stopped or interrupted before the III-nitride ELO layers 105 at adjacent opening areas 103 can coalesce on top of the growth restrict mask 102, wherein this interrupted growth results in the no-growth regions 104 between adjacent III-nitride ELO layers 105. Alternatively, the growth of the III-nitride ELO layers 105 may be continued and coalesce with neighboring III-nitride ELO layers 105, as shown in schematic 100B, thereby forming a coalesced region 106 of increased defects at a meeting region.

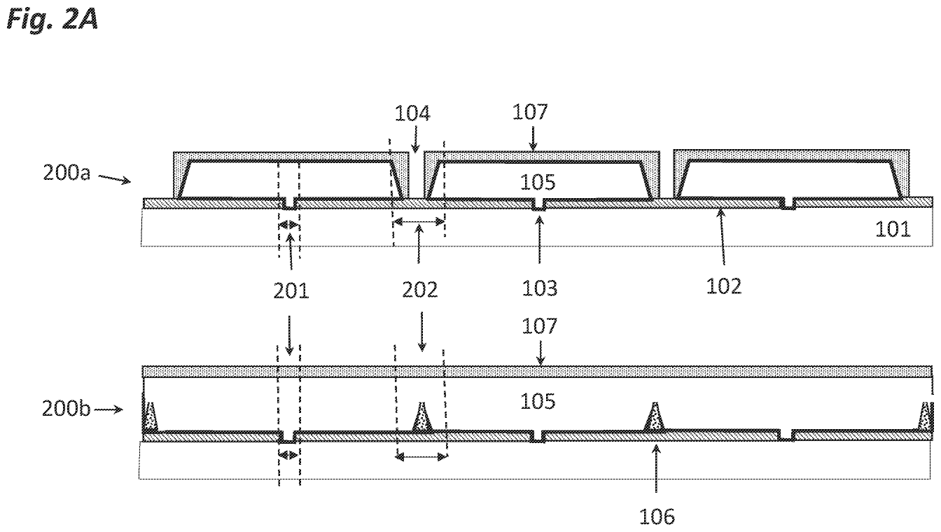

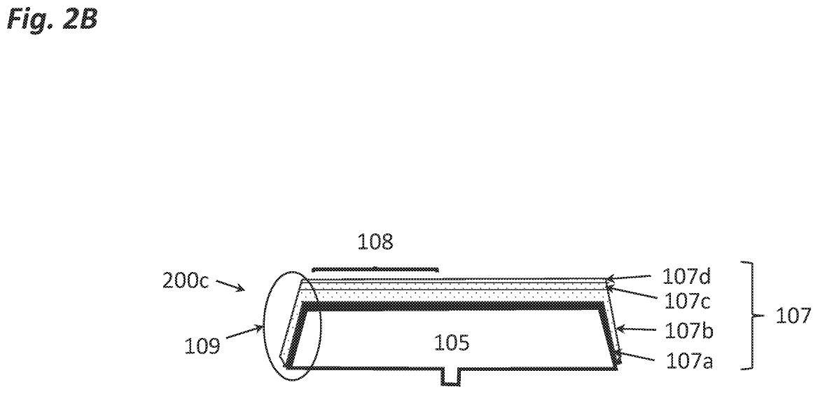

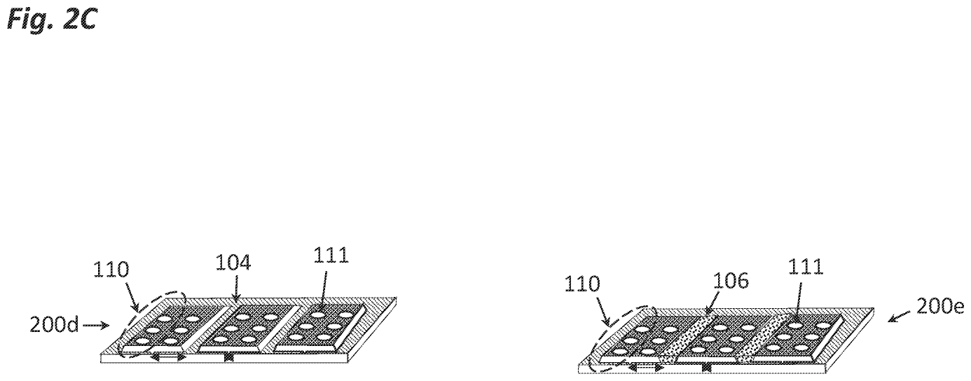

In FIGS. 2A, 2B and 2C, schematics 200a, 200b, 200c, 200d and 200e illustrate how additional III-nitride device layers 107 are deposited on or above the III-nitride ELO layers 105, and may include an active region 107a, p-type layer 107b, electron blocking layer (EBL) 107c, and cladding layer 107d, as well as other layers. The open region of the III-nitride ELO layer is labeled as region 201 and the region at the which the neighboring III-nitride ELO layer wings may or may not meet is labeled as region 202.

The III-nitride ELO layers 105 and III-nitride device layers 107 include one or more flat surface regions 108 and layer bending regions 109 at the edges thereof adjacent the no-growth regions 104, when the III-nitride ELO layers 105 stopped before coalescing as shown in 100a, or when the III-nitride ELO layers 105 continued to coalesce in a coalesced region 106 as shown in 100b. The width of the flat surface region 108 is at least 3 μm, and most preferably is 10 μm or more.

A light-emitting active region 107a of the devices 110 is processed at the flat surface regions 108 on either side of region 201, preferably between opening area 103 and the edge portion 109 or coalesced region 106. By doing so, a bar of a device 110 will possess an array of twin or nearly identical light emitting apertures 111 on either side of the opening area 103 along the length of the bar, as indicated in schematics 200d and 200e.

There are many methods of removing the light emitting regions from the substrate 101. For example, the present invention can utilize the ELO method for removing the light emitting devices 110. In the present invention, the bonding strength between the substrate 101 and the III-nitride ELO layers 105 is weakened by the growth restrict mask 102. In this case, the bonding area between the substrate 101 and the III-nitride ELO layers 105 is the opening area 103, wherein the width of the opening area 103 is narrower than the III-nitride ELO layers 105. Consequently, the bonding area is reduced by the growth restrict mask 102, so that this method is preferable for removing the epitaxial layers 105, 107.

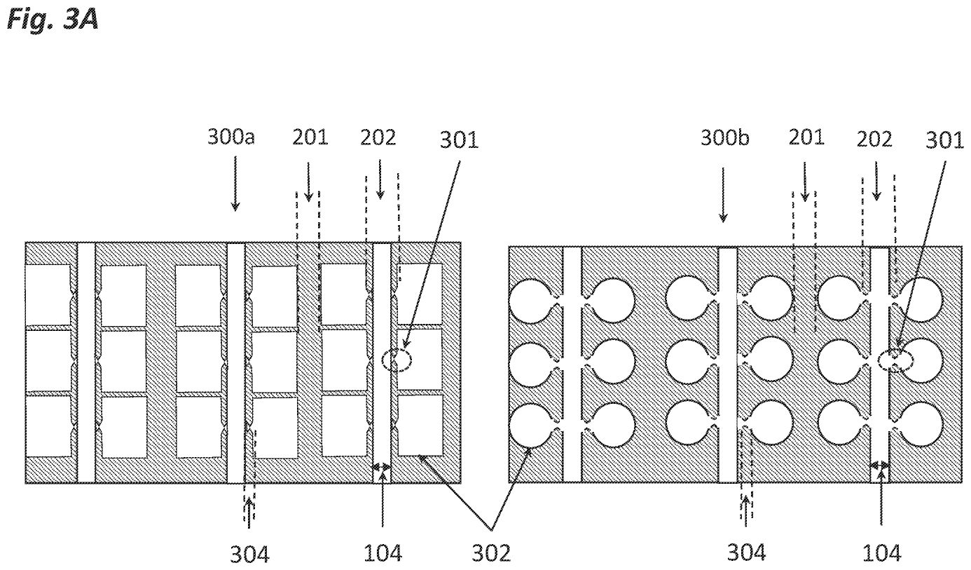

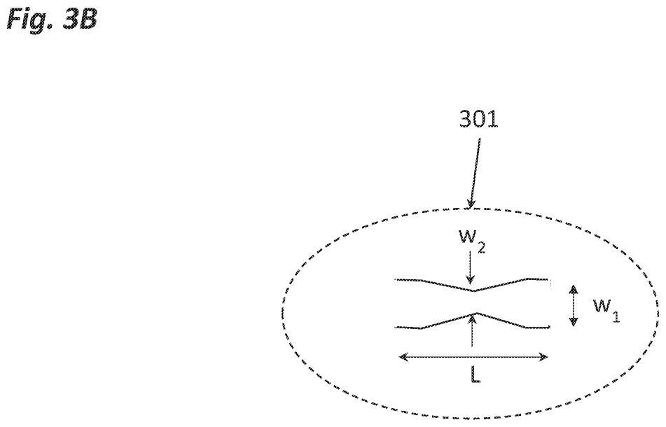

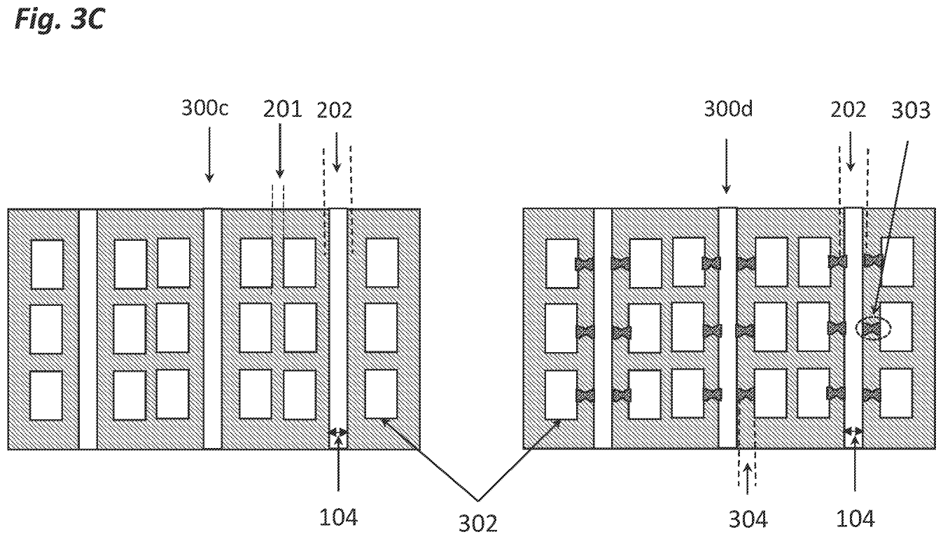

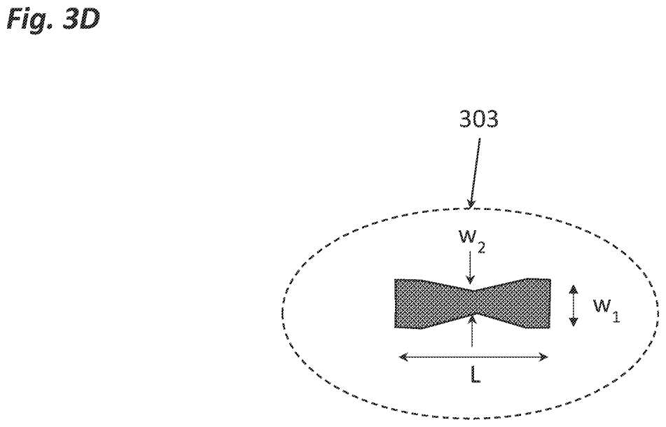

This invention proposes two approaches to realize micro-LED devices. In one approach, as shown in schematics 300a and 300b in FIGS. 3A and 3B, a connecting link comprising an epitaxial bridge 301 is formed. The epitaxial bridge 301 connects the region 202 and the device unit pattern 302. As shown in FIG. 3B, the epitaxial bridge 301 has a length L and a width W1, with a narrow taper of width W2 that is smaller than a width W1. The epitaxial bridge 301 can be formed while performing a desired device unit pattern 302, or alternatively, a separate etching step may be dedicated to realizing a non-epitaxial bridge 303. The device unit pattern 302 can be square, rectangular, circular or any arbitrary shape. To form the patterns 302 shown in FIG. 3A, region 201 and region 202 as described in FIG. 2 are etched in a plasma-based environment. This step isolates the device unit patterns 302 from the host substrate 101 while keeping an epitaxial bridge 301 with the host substrate 101.

Alternatively, as shown in the schematics 300c and 300d in FIGS. 3C and 3D, instead of an epitaxial bridge 301, a connecting link comprising a non-epitaxial bridge 303 may be created with a material other than the growth restrict mask 102 or even with the same material as the growth restrict mask 102. The separation length 304 at least partially stays on the wing region of the ELO layers 105, and ensures a good crystal quality for the light emitting aperture 111 and a fragile aspect when picking devices 110 using methods described later herein.

There are many methods of removing the light emitting regions from the substrate 101. For example, the present invention can utilize the ELO method for removing the light emitting devices 110. In the present invention, the bonding strength between the substrate 101 and the III-nitride ELO layers 105 is weakened by narrower design of W2 in the epitaxial bridge 301. Consequently, the bonding area is reduced, so this method is preferable for removing the epitaxial layers 105, 107.

In one embodiment, the III-nitride ELO layers 105 are allowed to coalesce to each other at region 106, as shown by schematic 100b in FIG. 1. After the III-nitride ELO layers 105 coalesce at region 106, subsequent III-nitride semiconductor device layers 107 are deposited. Light emitting element apertures 111 will be fabricated on the wings of the III-nitride ELO layers 105 away from the coalesced region 106 and region 201 later in the fabrication process.

As shown in FIGS. 3A and 3C, the III-nitride semiconductor layers 107 can be divided into device unit patterns 302 using, for example, a dry etching or laser scribing, etc. The separation distance 304 is a distance between the III-nitride ELO layers 105 after etching a portion of region 202. Moreover, the length L of the epitaxial bridge 301 or non-epitaxial bridge 303 is defined as the separation distance 304, which ensures a good crystal quality for light emitting apertures 111 on the wings of the III-nitride ELO layers 105 by positioning the device unit patterns 302 away from the no-growth region 104. In particular, at least a 1 μm distance from the no-growth region 104 would ensure a good crystal quality for the light emitting aperture 111.

The device unit patterns 302 may comprise light emitting apertures 111 as mentioned above, that are located at a separate distance 304 in separate regions 202 placed directly on or above the growth restrict mask 102 for the sake of facilitating the removal of the devices 110. The separate distance 304 is preferably 1 μm or more, which facilitates the breaking of the epitaxial bridge 301 or the non-epitaxial bridge 303 by fracturing and/or cleaving of the connecting link.

Preferably, the edge of the light emitting aperture 111, which is emitting a predetermined wavelength light by applying a current, is more than 1 μm away from the edge of the region 202. When the separate region 202 is fractured to remove the device 110, it may damage the emitting aperture 111. More preferably, the emitting aperture 111 is 2 μm or more away from the edge of the region 201, which reduces the number of defects in in the aperture 111 area.

By doing this, there is a greater process tolerance for the yield. As can be seen in the FIGS. 3A and 3C, the device unit patterns 302 are shown with the epitaxial bridge 301 or non-epitaxial bridge 303 with the host substrate 101.

Two approaches to the epitaxial bridge 301 or non-epitaxial bridge 303 follow.

(i) Epitaxial Bridge to Hold Regrowth Layer of p-Type

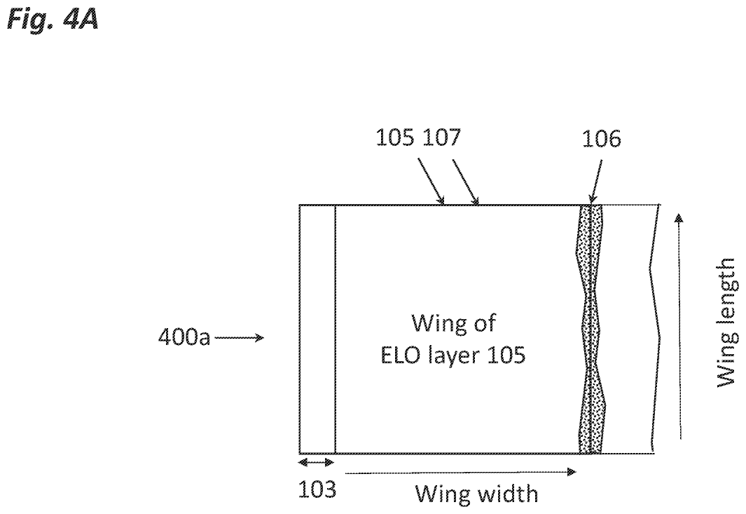

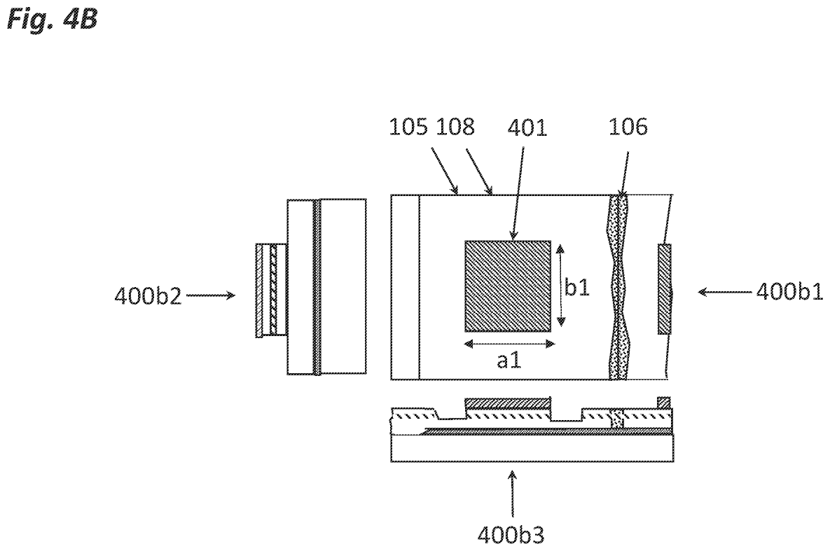

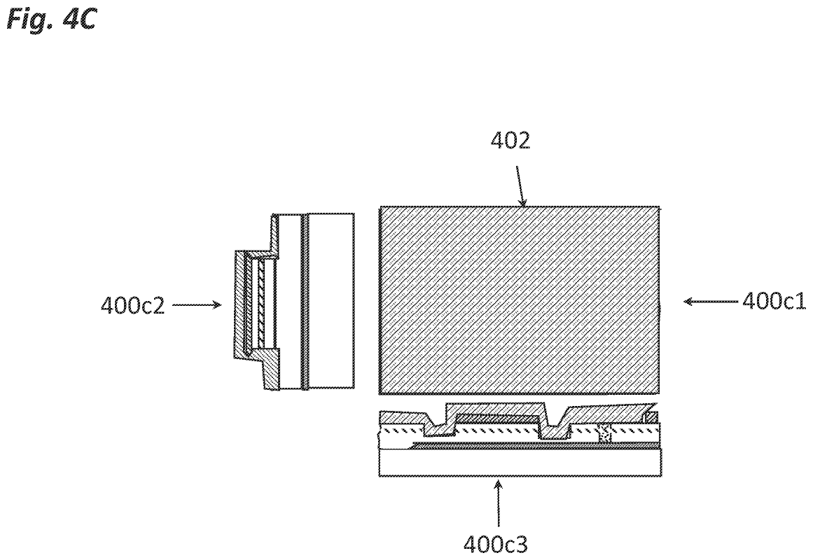

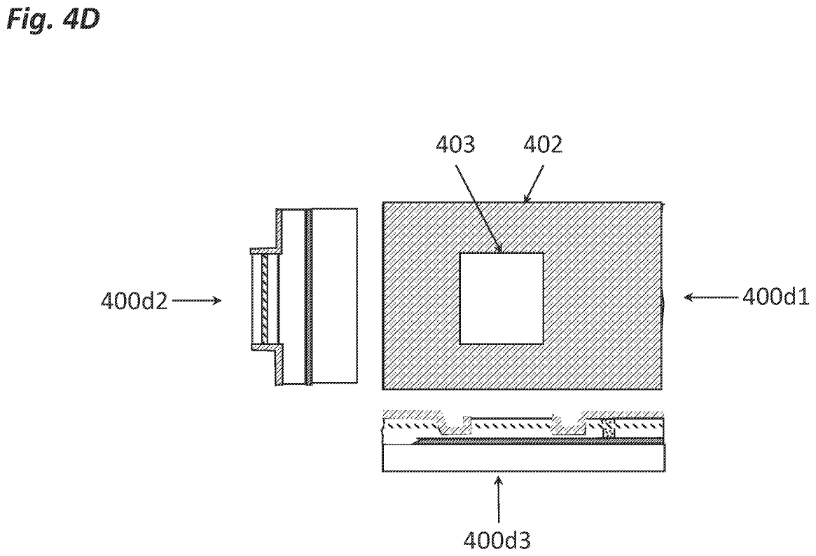

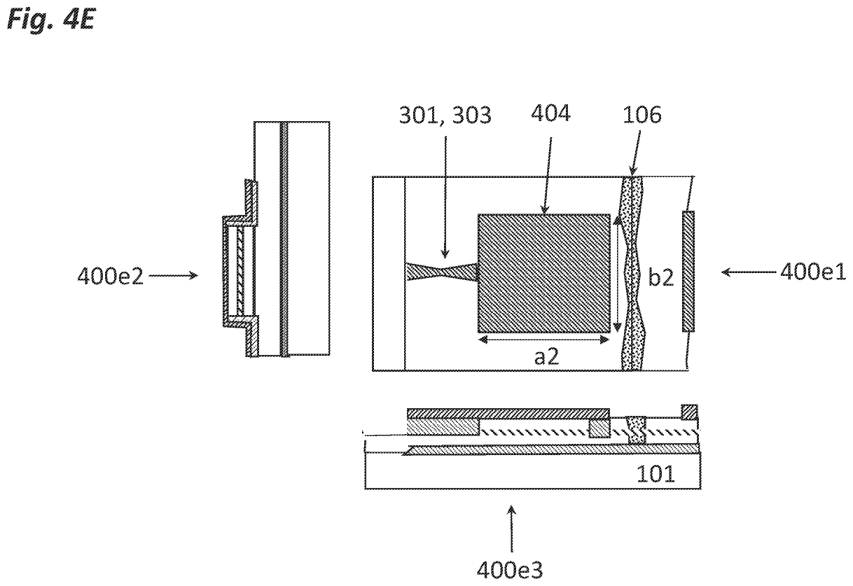

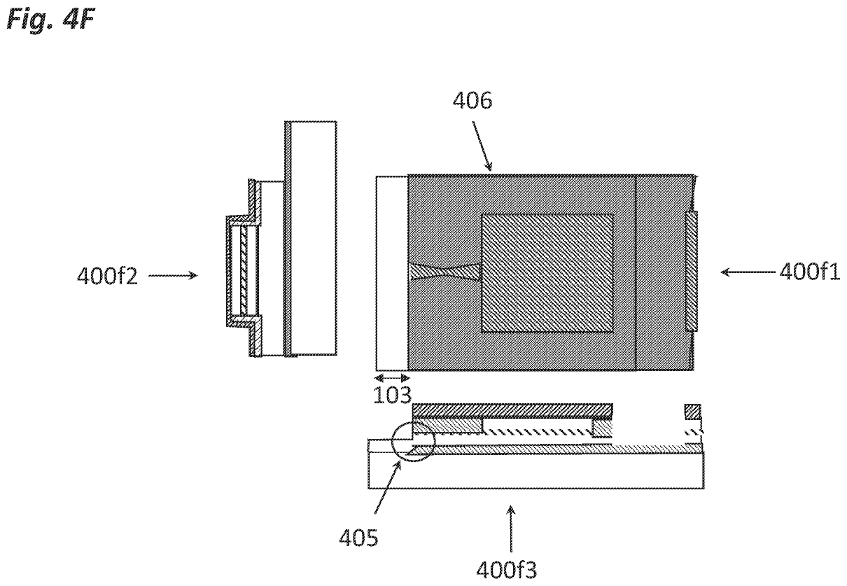

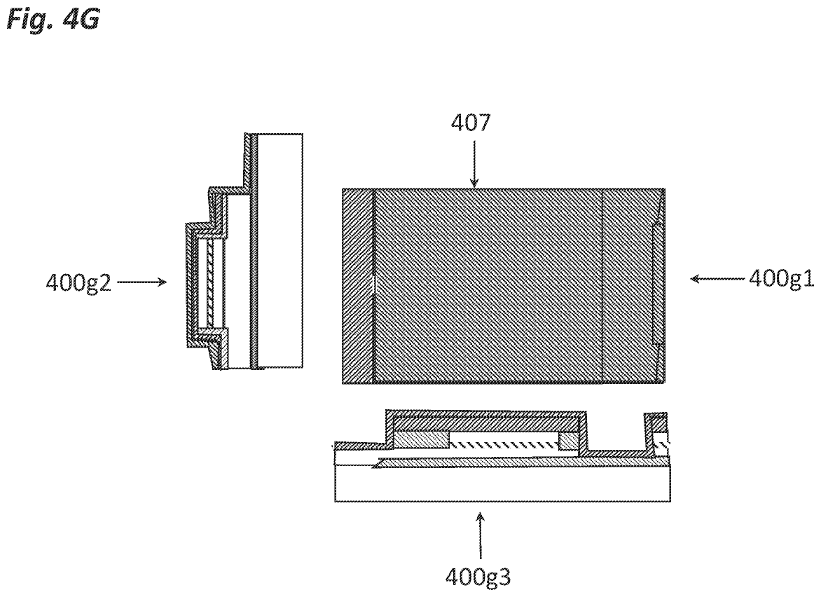

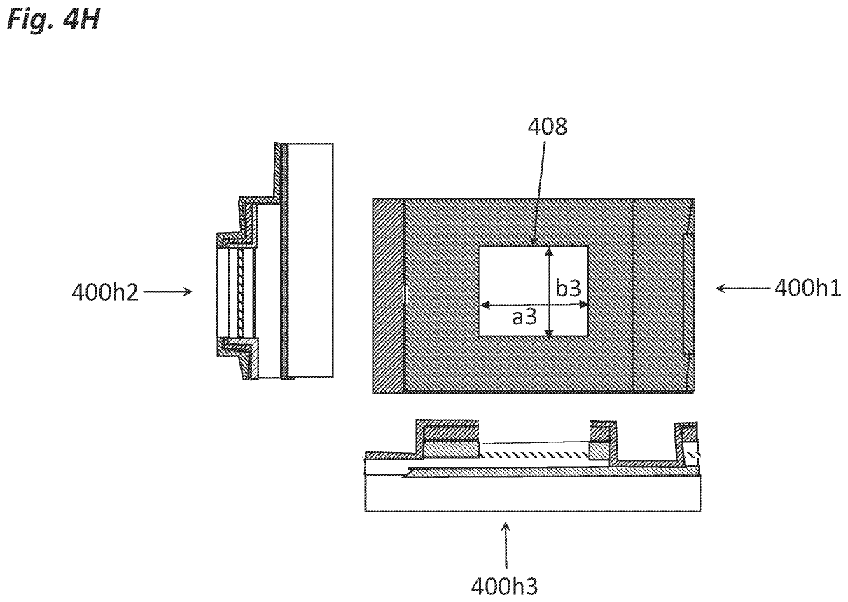

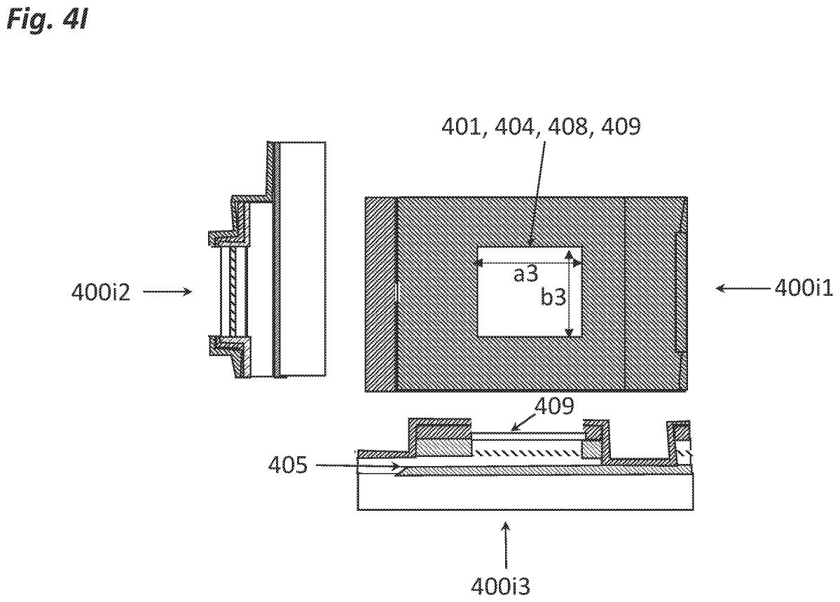

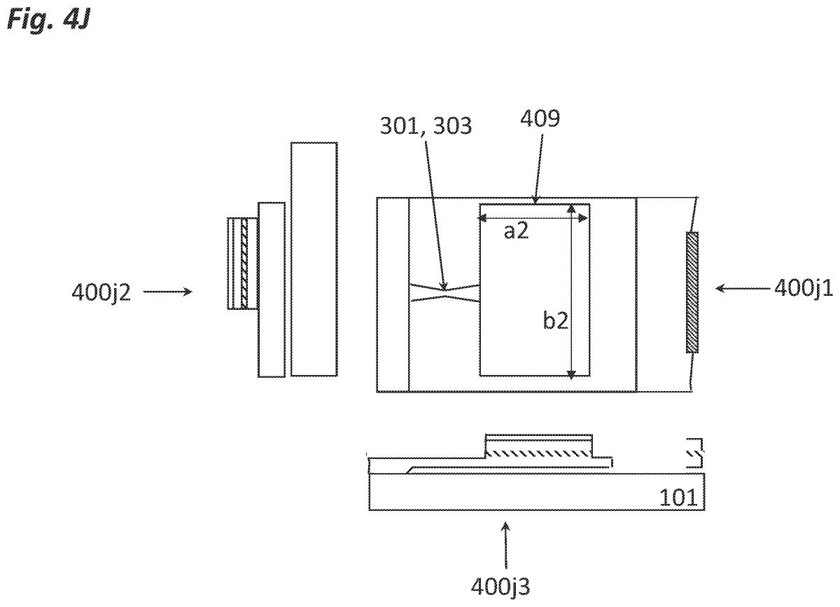

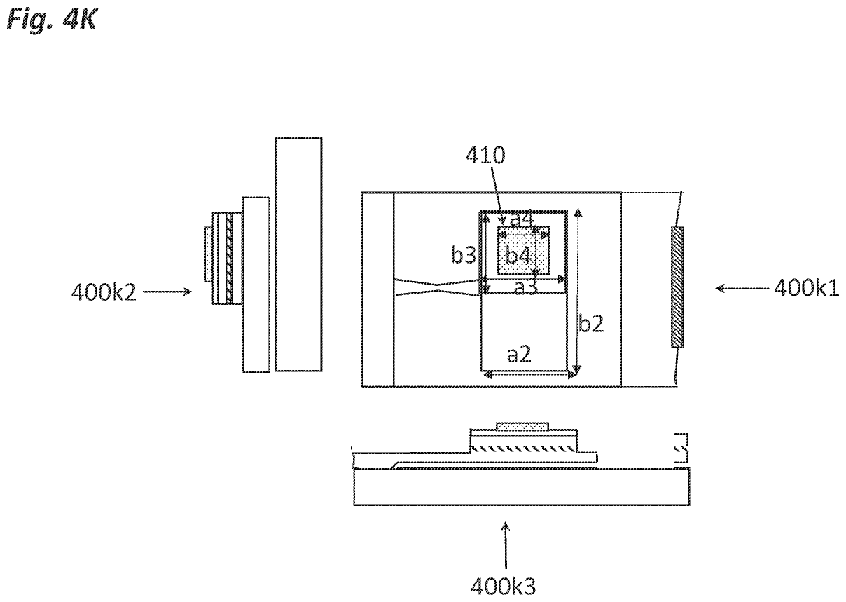

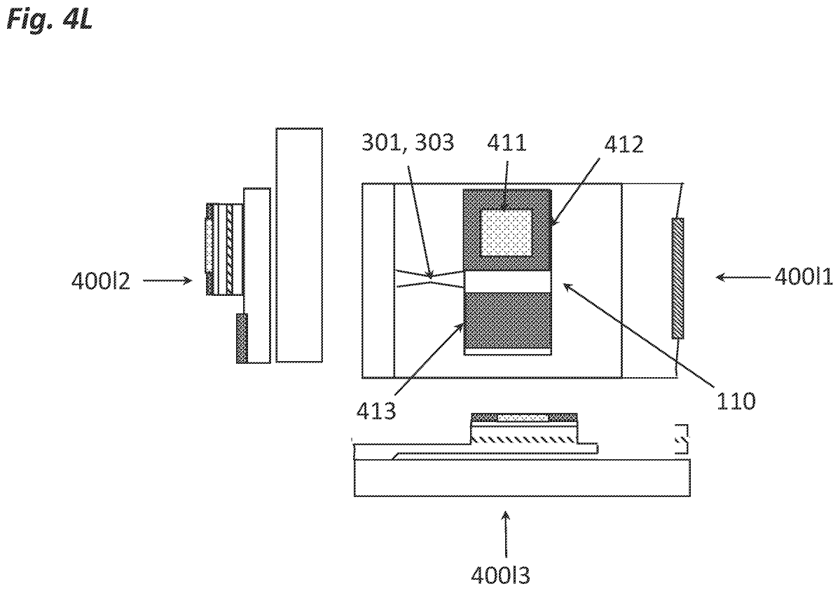

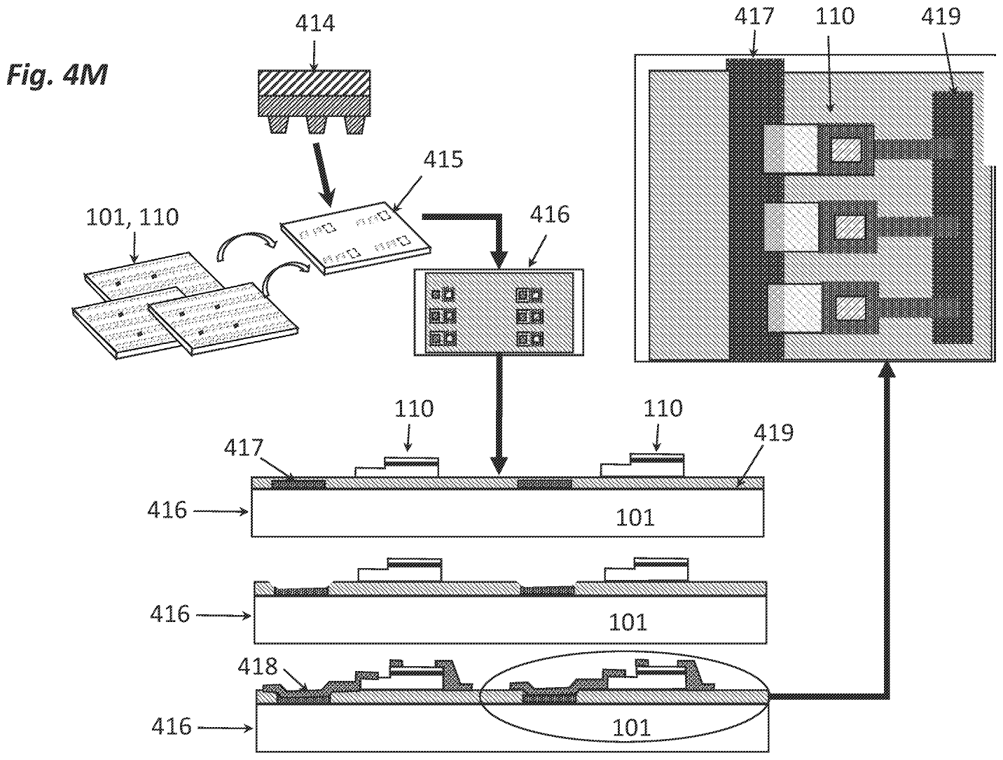

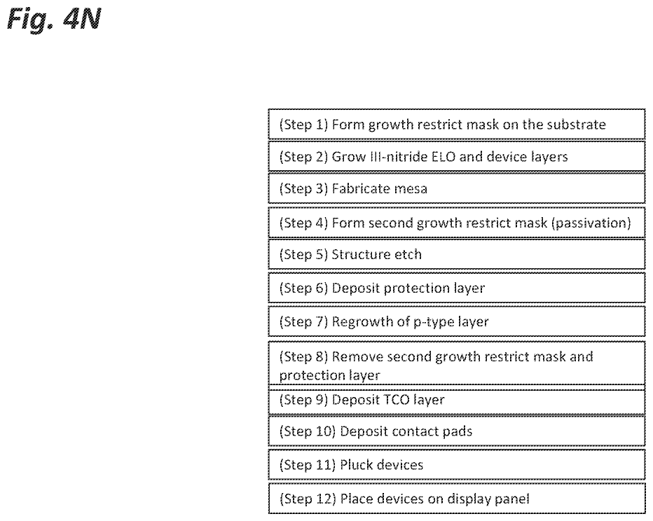

For clarity, this description is limited to one device 110, as described in FIGS. 4A-4N. In one approach, the epitaxial device layers 107 are comprised of a complete device structure, i.e., at least an n-type region, active region and p-type region.

The typical fabrication steps for this invention are described in more detail below:
Step 1: Forming a growth restrict mask 102 with a plurality of striped opening areas 103 directly or indirectly upon a substrate 101, wherein the substrate 101 is a III-nitride-based semiconductor, or the substrate is a hetero-substrate (Si, SiN, Sapphire, etc.), or the template prepared including growth restrict masks 102.
Step 2: As shown in the schematic 400a in FIG. 4A, growing the III-nitride ELO layers 105 on or above the substrate 101 using the growth restrict mask 102, such that the growth extends in a direction parallel to the striped opening areas 103 of the growth restrict mask 102, with wings of the III-nitride ELO layers 105 on either side of the opening areas 103, coalescing into regions 106. Thereafter, growing a plurality of epitaxial device layers 107 on the III-nitride ELO layers 105. This step isolates the III-nitride ELO layers 105 and device layers 107 on the growth restrict mask 102, while forming a connecting link comprising the bridge 301, 303 between the substrate 101 and the isolated III-nitride ELO layers 105 and device layers 107.
Step 3: As shown in the schematics 400b1 (top view), 400b2 (side view), 400b3 (side view) in FIG. 4B, a light emitting mesa 401 with an area a1×b1 is fabricated on a wing of the III-nitride ELO layers 105, away from the coalesced region 106, and on the flat surface region 108, using a photo mask and conventional methods, and exposing the underlying layers by plasma-based environment etching.
Step 4: As shown in the schematics 400c1 (top view), 400c2 (side view), 400c3 (side view) in FIG. 4C, a second growth restrict mask 402 is blanket deposited, where this second growth restrict mask 402 can be a similar material as used previously for ELO patterning or a different material. This second growth mask 402 may also have a function to passivate to heal or improve the damage associated in the plasma-based etching. As shown in the schematics 400d1 (top view), 400d2 (side view), 400d3 (side view) in FIG. 4D, a liftoff of a selectively masked region 403 can be performed while protecting the surrounding etched portion.
Step 5: As shown in the schematics 400e1 (top view), 400e2 (side view), 400e3 (side view) in FIG. 4E, forming a structure 404 having an area (a2× b2) larger than the previous light emitting mesa 401, which has an area (a1× b1), for separating devices 110, wherein devices 110 are separated from each other and the connection with the host substrate 101 by previously mentioned bridges 301, 303 is maintained. As shown in the schematics 400f1 (top view), 400f2 (side view), 400f3 (side view) in FIG. 4F, a long etch is performed at least to expose the underlying growth restrict mask 102. In this step, during the long etch, the epitaxial bridge 301 design was such that an n-type layer link 405 remains with the open area 103. The mesa etch layer 406 used for forming a mesa (a2× b2) can be a hard mask, such as SiO₂, SiN etc. Alternatively, a photo resist (PR) mask may also be used.
Step 6: As shown in the schematics 400g1 (top view), 400g2 (side view), 400g3 (side view) in FIG. 4G, a protection layer 407 is blanket deposited. The layers 406 and 407 can be the same material or different materials. The layer 407 protects the exposed mesa 401 during the formation of structure 404. As shown in the schematics 400h1 (top view), 400h2 (side view), 400h3 (side view) in FIG. 4H, a regrowth area 408, which has an area (a3× b3), is defined. When using a photo resist mask to define the structure 404, with an area (a2× b2), then a lift off is performed to realize the structure 404, after blanket depositing the protection layer 407. Otherwise, the protection layer 407 and mesa etch layer 406 are selectively exposed on a p-layer for the regrowth.
Step 7: As shown in the schematics 400i1 (top view), 400i2 (side view), 400i3 (side view) in FIG. 4I, the structure 404 is returned to a crystalline layer growth environment. Since the exposed regrowth area 408 is comprised of a p-type region, active region and n-type region, care must be taken for the regrowth layer. An MBE or reduced temperature environment must be used to regrow a thin higher doping p-type layer over the exposed regrowth area 408. Alternatively, pulsed laser deposition (PLD) or pulsed sputtering deposition (PSD) techniques may also be used to avoid damage to the previously grown active region. The epitaxial bridge 301 (not shown) and the epitaxial layer link 405 can be strong enough to hold the isolated structure 404, even at slightly elevated parameters. However, in this scenario, to avoid a degradation of the active region, one may choose any of the above mentioned deposition methods to regrow the thin highly doped p-type layer 409. Re-growing a high carrier density p-type layer 409 over the etched mesa 401 will heal the damage caused by the plasma-based etching environment.
Step 8: As shown in the schematics 400j1 (top view), 400j2 (side view), 400j3 (side view) in FIG. 4J, the second growth restrict mask 402 and protection layer 407 are dissolved using a chemical etchant, such as buffered hydrofluoric acid (BHF) or a hydrofluoric acid (HF), resulting in the epitaxial bridge 301 or non-epitaxial bridge 303 as a hanging bridge.
Step 9: As shown in the schematics 400k1 (top view), 400k2 (side view), 400k3 (side view) in FIG. 4K, a transparent conducting oxide (TCO) layer 410, such as ITO (Indium Tin Oxide), is deposited over the hanging-bridge devices 110. The patterning mesa structure of the TCO layer 410, with an area (a4× b4), is chosen to be smaller than the regrowth area 408, with an area (a3× b3), so that the difference may be used to place a p-type electrical conducting layer.
Step 10: As shown in the schematics 40011 (top view), 40012 (side view), 40013 (side view) in FIG. 4L, electrical contact pads 411 are laid over a p-type layer 412 and n-type layer 413 for electrical injection.
Step 11: The completed micro-LED device 110 has a very delicate hanging bridge 301, 303 to the host substrate 101. The bridge 301, 303 strength can be designed to be delicate by controlling the parameters of bridges 301, 303. As shown in the schematic of FIG. 4M, the hanging bridge micro-LEDs 110 realized at step 10 are plucked from the host substrate 101 by a stamp 414, vacuum chuck, etc. For example, when a c-plane substrate is used, the epitaxial bridge 301 may utilize the cleavability of the m-plane to break the epitaxial bridge 301 for the sake of removing the micro-LED device 110. When using the epitaxial bridge 301, the mechanical force of the stamp 414 or vacuum chuck can easily break the link 301 to separate devices 110 from the host substrate 101.
Step 12: The plucked LED devices are placed on an intermediate imposer 415, and then the LED devices are dispersed from the imposer to a display panel 416. The display panel 416 has an embedded electrode track pad for n-type electrical connection 417 and a p-pad electrical track 418 is placed on an insulator or separator 419. The micro-LED display 416 can be used in several applications, such as TVs, laptops, phones, AR/VR/MR, HUDs, retina display applications, etc.

FIG. 4N is a flowchart further illustrating Steps 1-12 set forth above.

(ii) Epitaxial Bridge to Hold Regrowth Layers of n-Type, Active Region and p-Type

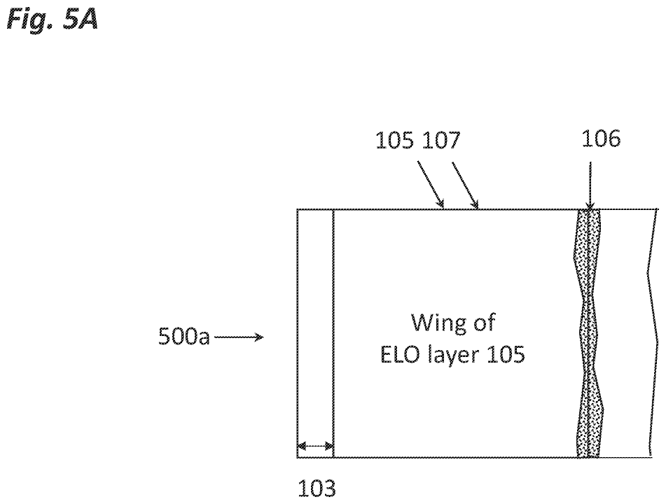

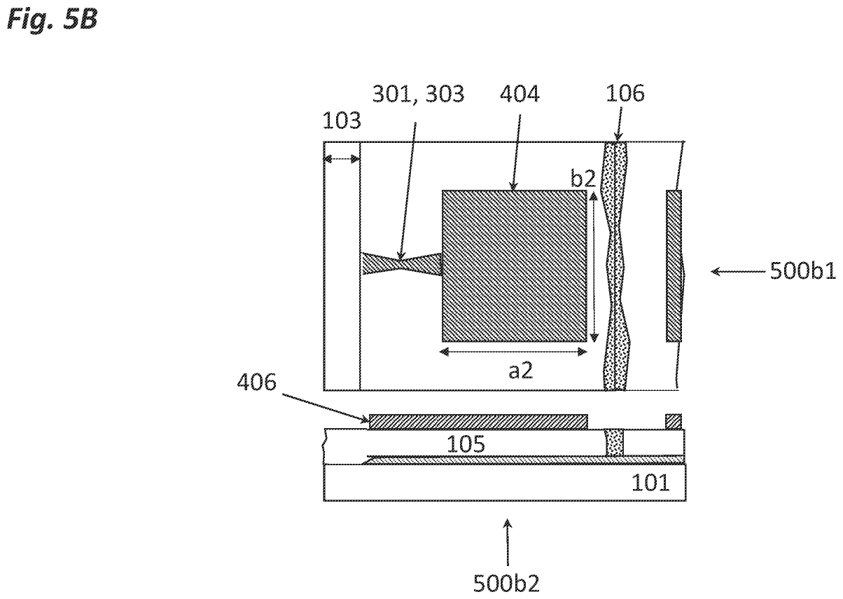

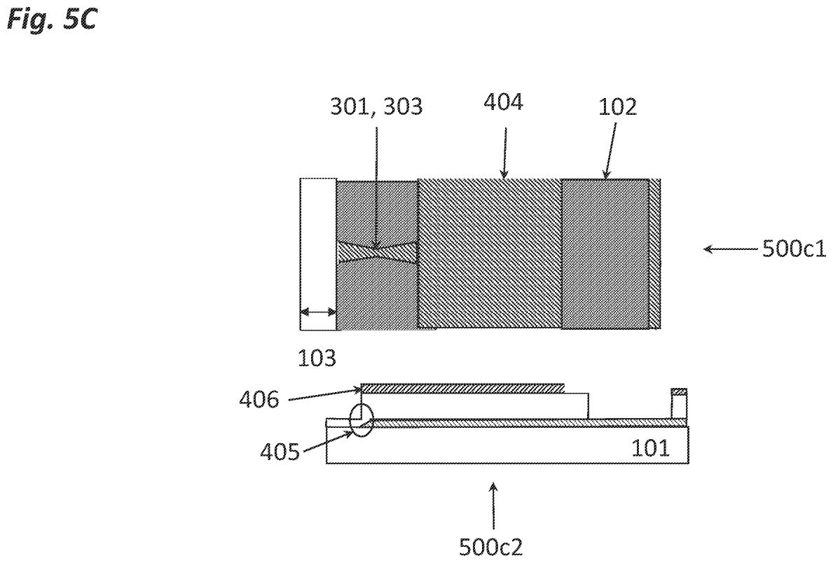

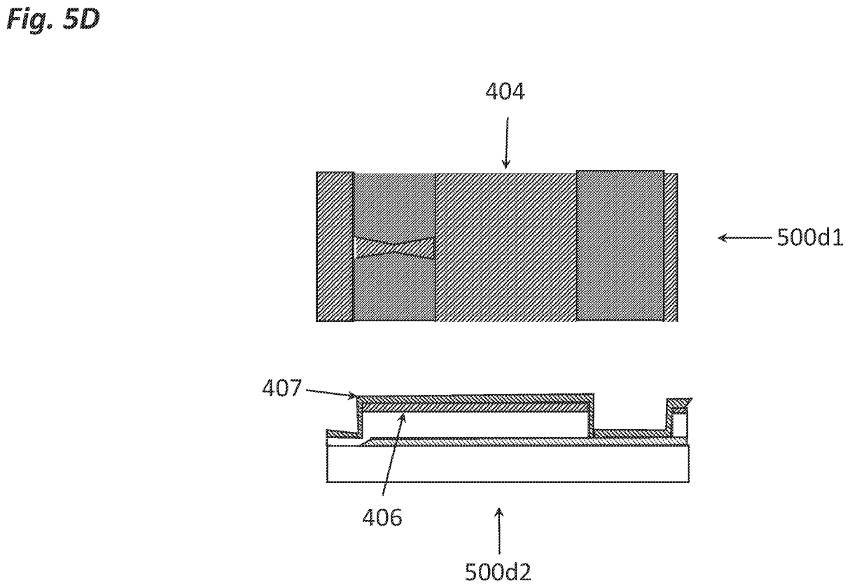

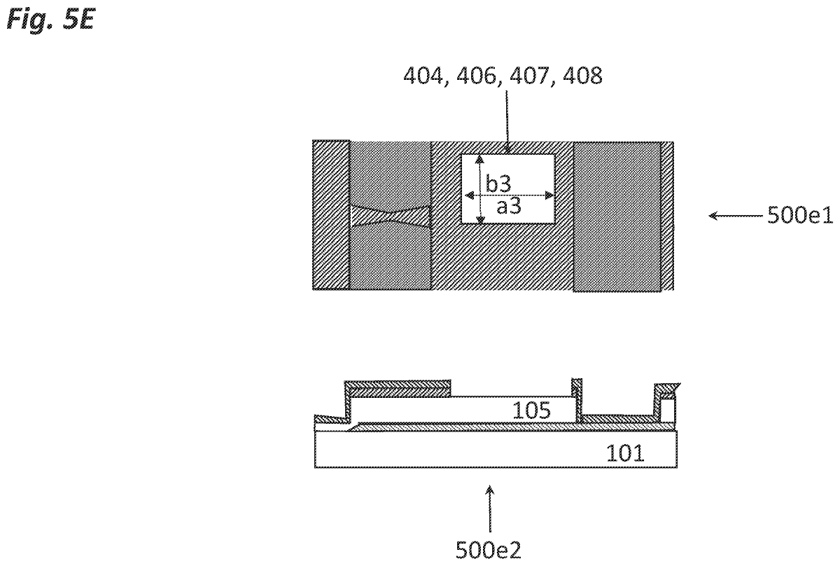

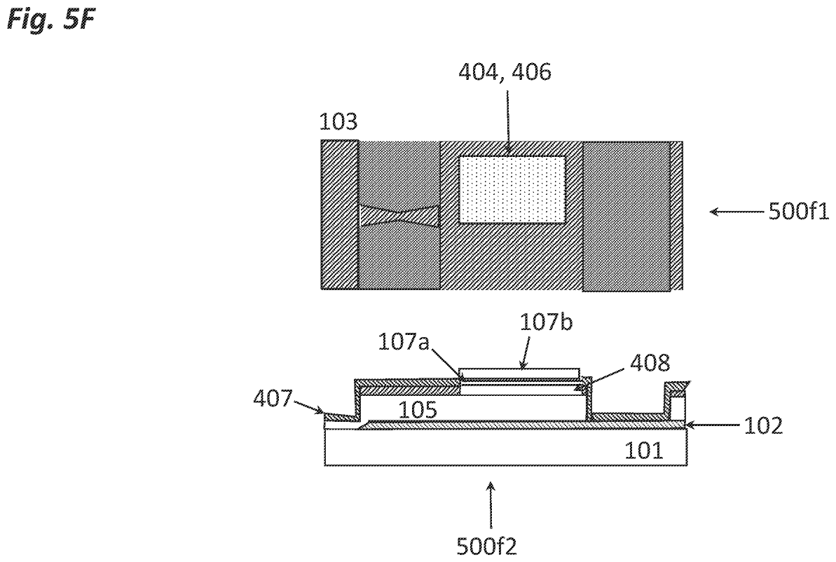

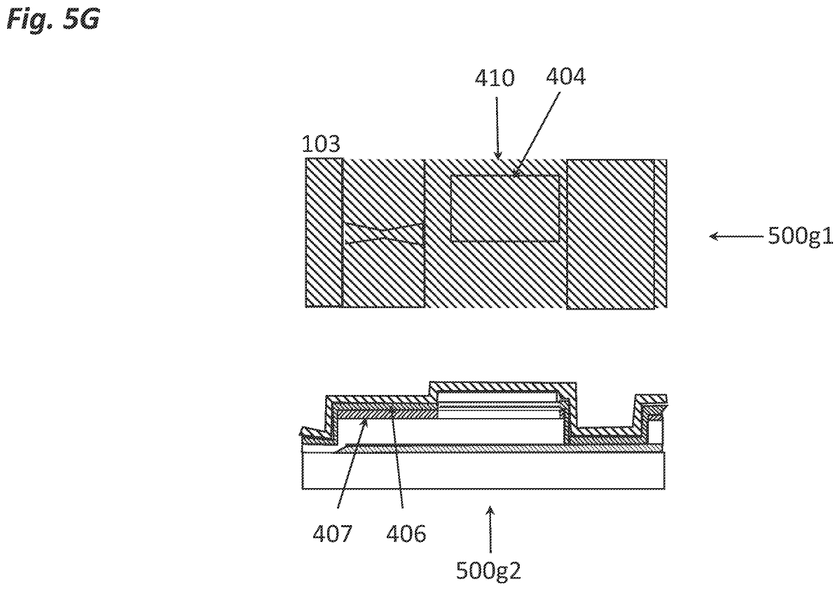

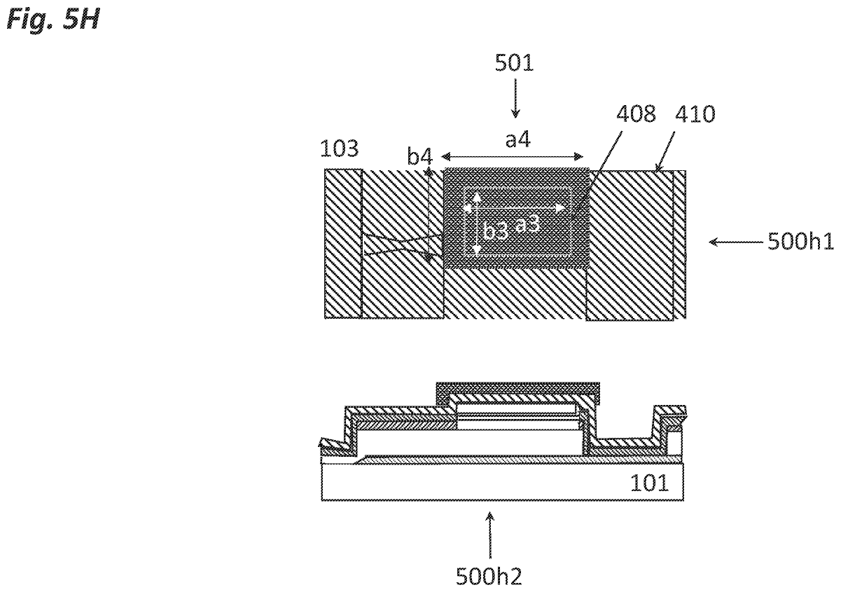

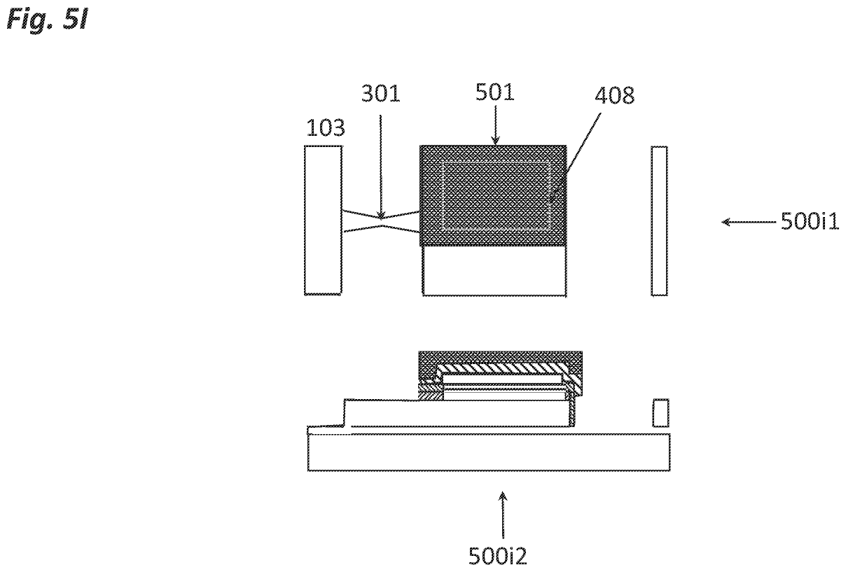

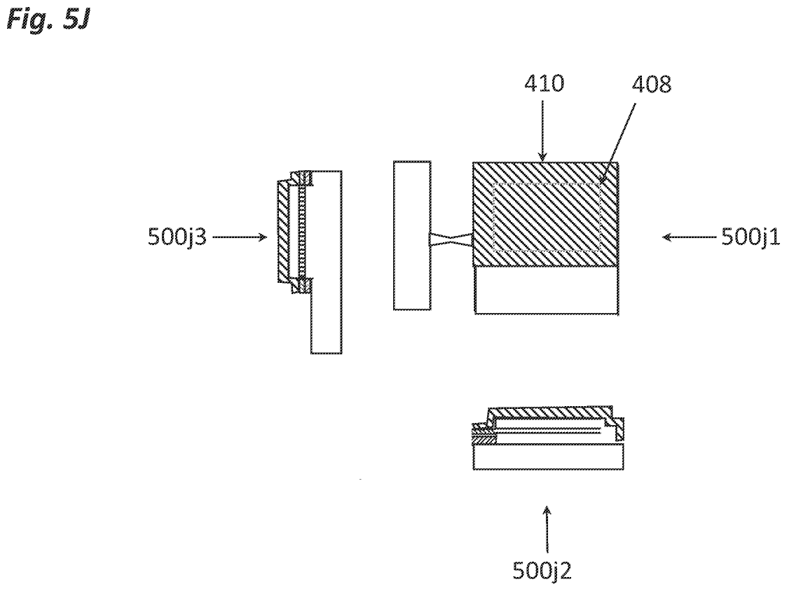

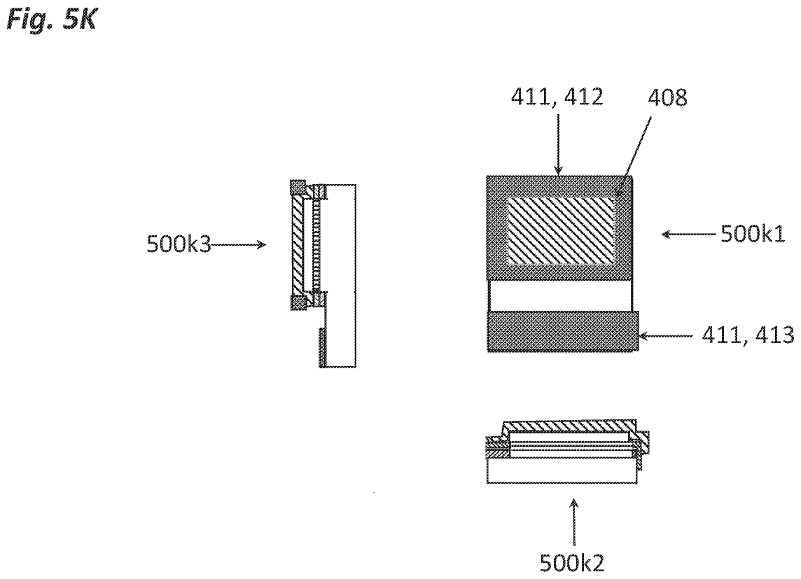

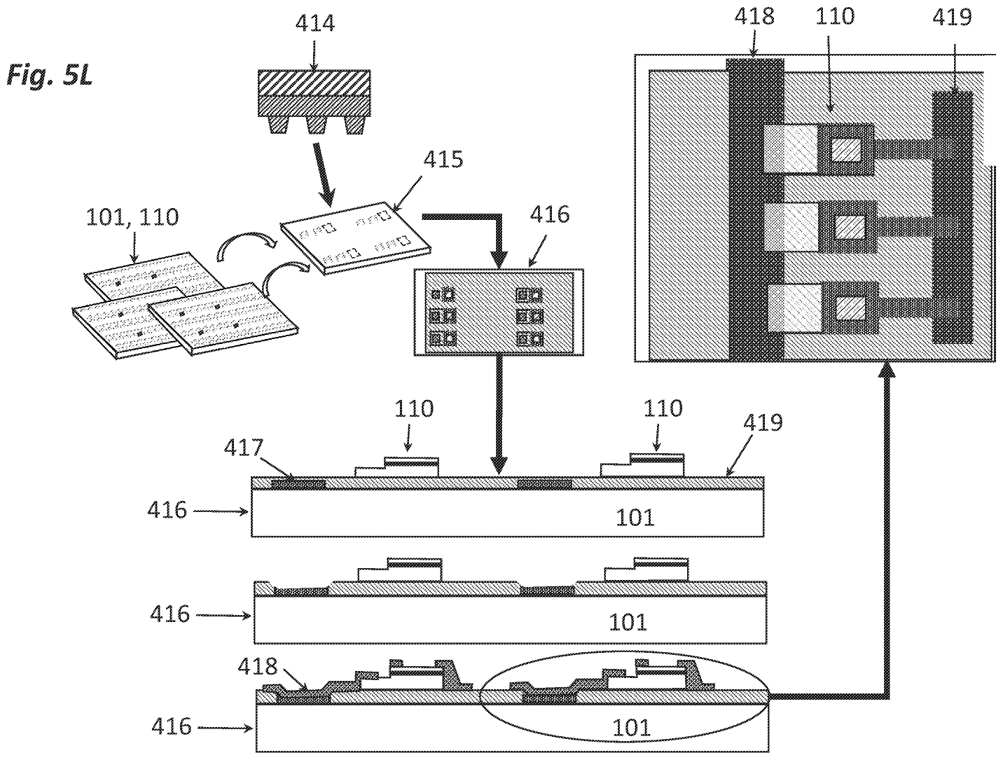

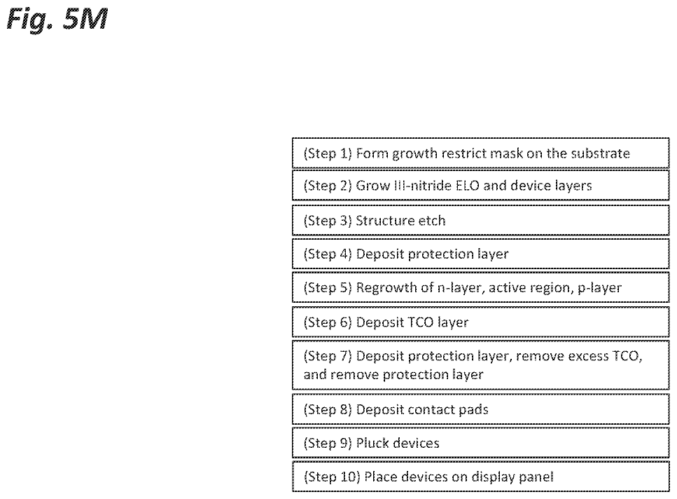

For clarity, this description is limited to one device unit, as described in FIGS. 5A-5N. In this approach, the epitaxial layers consists only of n-type layers before performing a regrowth.

The typical fabrication steps for this invention are described in more detail below:
Step 1: Forming a growth restrict mask 102 with a plurality of striped opening areas 103 directly or indirectly upon a substrate 101, wherein the substrate 101 is a III-nitride-based semiconductor, or the substrate is a hetero-substrate, or the template prepared including growth restrict masks.
Step 2: As shown in the schematic 500a in FIG. 5A, growing a plurality of III-nitride ELO layers 105 upon the substrate 101 using the growth restrict mask 102, such that the growth extends in a direction parallel to the striped opening areas 103 of the growth restrict mask 102, with wings of the III-nitride ELO layers 105 on either side of the opening areas 103, coalescing into regions 106. Thereafter, growing a plurality of epitaxial device layers 107 on the III-nitride ELO layers 105.
Step 3: As shown in the schematics 500b1 (top view), 500b2 (side view) in FIG. 5B, forming a structure 400 having an area (a2× b2) for separating n-type layers into isolated devices 110. The isolation separates each device 110 from its neighbor and keeps the connection of the bridges 301, 303 with the host substrate 101. As shown in the schematics 500c1 (top view), 500c2 (side view) in FIG. 5C, a deeper etch is performed at least to expose underlying ELO growth restrict mask 102. In this step, during the long etch of the epitaxial bridge 301, the design is such that an n-type layer link 405 remains with the open area 103. The layer 406 used for forming a mesa (a2× b2) can be a hard mask, such as SiO₂, SiN etc., or a photo resist (PR) may also be used.
Step 4: As shown in the schematics 500d1 (top view), 500d2 (side view) in FIG. 5D, a protection layer 407 is blanket deposited. The layers 407 and 406 can be from the same material or a different material. The layer 407 protects the exposed mesa 401 during the formation of the structure 404 (a2× b2). As shown in the schematics 500e1 (top view), 500e2 (side view) in FIG. 5E, a regrowth area 408, which has an area (a3× b3), is defined. When using a photo resist mask to define the structure 404, with an area a2× b2, then a lift off is performed to realize the structure 404, after blanket depositing the protection layer 407; otherwise, the protection layer 407 and mesa etch layer 406 are selectively exposed on a n-type layer for the regrowth.
Step 5: As shown in the schematics 500f1 (top view), 500f2 (side view) in FIG. the structure 404 is sent back to a crystalline layer growth environment. Since the exposed regrowth area 408 comprises an n-type layer, an n-layer, active region and p-type are grown in the regrowth step. As there is no active region previously involved, the usual MOCVD chamber may be used to regrow a full device 100 structure. Alternatively, MBE or a reduced temperature environment, pulsed laser deposition (PLD), or pulsed sputtering deposition (PSD) techniques may also be used. The epitaxial bridge 301 and the epitaxial layer link 405 can be strong enough to hold the isolated structure 404, even at elevated parameters.
Step 6: As shown in the schematics 500g1 (top view), 500g2 (side view) in FIG. 5G, a TCO layer 410 is deposited over the regrown layers of the isolated structure 404, as well as the protection layer 407 and mesa etch layer 406.
Step 7: As shown in the schematics 500h1 (top view), 500h2 (side view) in FIG. 5H, a protection mesa 501, with an area a4× b4, is placed over the regrowth area 408, which is now the light emitting region, to protect the TCO layer 410. As shown in the schematics 500i1 (top view), 500i2 (side view) in FIG. 5I, the remaining TCO layer 410 and the protection layer 407 are removed, resulting in the epitaxial bridge 301 maintaining the only connection to the host substrate 101. As shown in the schematics 500j1 (top view), 500j2 (side view) in FIG. 5J, the protection mesa 501 is removed from the regrowth area 408.
Step 8: As shown in the schematics 500k1 (top view), 500k2 (side view), 500k3 (side view) in FIG. 5K, electrical contact pads 411 are laid over p-type layers 412 and n-type layer 413 for electrical injection.
Step 9: The completed micro-LED device 110 has a very delicate hanging bridge 301, 303 to the host substrate 101. The bridges 301, 303 strength can be designed to be delicate by controlling the parameters of the bridges 301, 303. As shown in the schematic of FIG. 5L, the hanging bridge micro-LEDs 110 realized at step 8 are plucked from the host substrate 101 by a stamp 414, vacuum chuck, etc. When using the epitaxial bridge 301, the mechanical force of the stamp 414 or vacuum chuck can easily break the link 301 to separate devices 110 from the host substrate 101.
Step 10: The plucked LED devices are placed on an intermediate imposer 415, and then the LED devices are dispersed from the imposer to a display panel 416. The display panel 416 has an embedded electrode track pad for n-type electrical connection 417 and a p-pad electrical track 418 is placed on an insulator or separator 419. The micro-LED display 416 can be used in several applications, such as TVs, laptops, phones, AR/VR/MR, HUDs, retina display applications, etc.

FIG. 5M is a flowchart further illustrating Steps 1-10 set forth above.

Vertical Pad Configuration

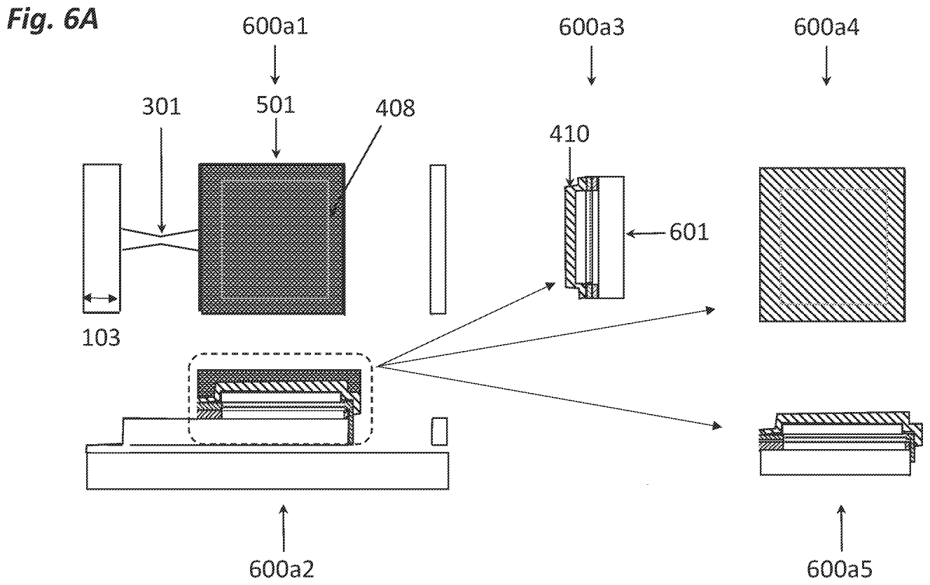

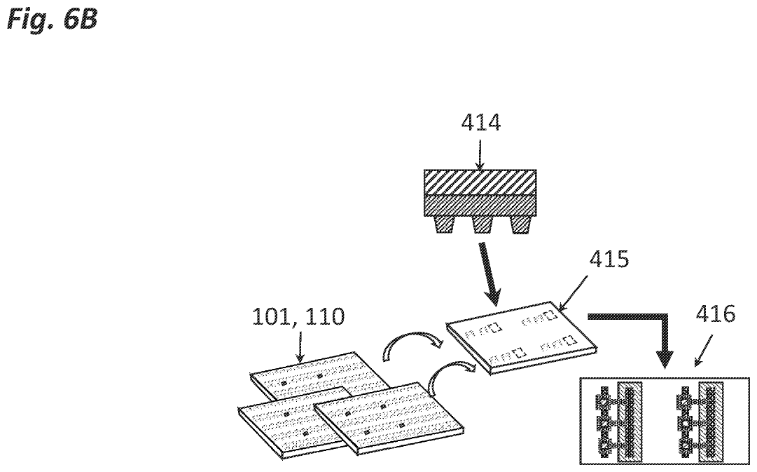

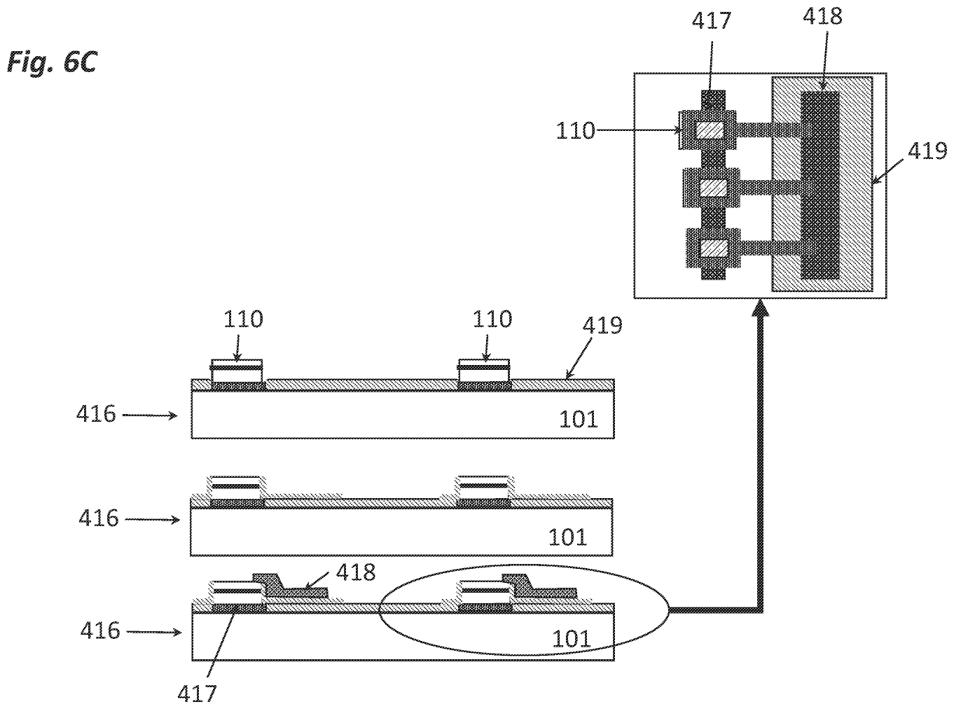

The epitaxial bridge 301 may also be applied to derive a vertical pad configuration chip, as indicated in FIGS. 6A, 6B and 6C. This is independent of the method of approach to derive a device 110, i.e., whether the regrowth was performed for only p-type layers, or whether a complete LED structure was grown. The backside interface 601, i.e., the interface between growth restrict mask 102 and the ELO layer 105, can be used as an n-type current injection layer, as shown in the schematics 600a1 (top view), 600a2 (side view), 600a3 (side view), 600a3 (top view), 600a5 (side view) in FIG. 6A. As shown in the schematic of FIG. 6B, the LEDs 110 are plucked from the host substrate 101 by a stamp 414, vacuum chuck, etc. The plucked LED devices 110 are placed on an intermediate imposer 415, and then the LED devices are dispersed from the imposer 415 to a display panel 416. As shown in the schematics of FIG. 6C, the display panel 416 has an embedded electrode track pad for n-type electrical connection 417 and a p-pad electrical track 418 is placed on an insulator or separator 419. The micro-LED display 416 can be used in several applications, such as TVs, laptops, phones, AR/VR/MR, HUDs, retina display applications, etc.

In the separation process regions 201, 202 are etched at least to expose growth restrict mask 102, if necessary, and the III-nitride ELO layers 105 are divided into individual devices 110 or are kept together as a group of devices 110. The divided III-nitride ELO layers 105 still remain on the growth restrict mask 102 of the host substrate 101 for processes such as solvent cleaning, UV ozone exposer, etc. Therefore, cleaning the III-nitride ELO layers 105 after separation using a RIE or some other technique will help to remove residues and may also help to prepare the surface for a bonding process or chemical treatments for recovering etch damage. This is a big advantage for reducing the process time and cost. Alternatively, as indicated above, the protection layer 407 still serves as an assist layer to secure the III-nitride device layers to the host substrate.

Many kinds of materials can be used as the protection layer 407, such as SiOx, SiNx, AlOx, SiONx, AlONx, TaOx, ZrOx, AlNx, TiOx, NbOx and so on (where x>0). It is preferable that the protection layer 407 is a transparent layer for light from the active region 107a of the device 110, because then there is no need to remove the protection layer 407 after removing the III-nitride ELO layers 105 from the substrate 101. Alternatively, the protection layer 407 may be an insulation layer. If the protection layer 407 is not an insulation layer, the protection layer 407 connects a p-type layer 107b and a n-type layer 405 of the device 110, which eventually would result in a short current, in which case, the protection layer 407 has to be removed. Thus, the protection layer 407 should be transparent and an insulation layer.

Moreover, AlONx, AlNx, AlOx, SiOx, SiN, SiON can passivate the device 110 surface, especially an etched GaN crystal. Since the protection layer 407 covers the side walls of the device 110, choosing these materials is preferable to reduce current leakage which flows from the side walls of the device 110. Moreover, the smaller the size of the device 110, the more the current leakage. Passivating the side walls of the device 110 is very important, especially at the separate region.

Forming a Growth Restrict Mask

In one embodiment, the III-nitride layers 105 are grown by ELO on a III-nitride substrate 101, such as an m-plane GaN substrate 101 patterned with a growth restrict mask 102 comprised of SiO₂, wherein the III-nitride ELO layers 105 may or may not coalesce at 106 on top of the growth restrict mask 102.

The growth restrict mask 102 is comprised of striped opening areas 103, wherein the SiO₂ stripes of the growth restrict mask 102 between the opening areas 103 have a width of 1 μm-20 μm and an interval of 10 μm-100 μm. If a nonpolar substrate is used, the opening areas 103 are oriented along a <0001> axis. If semipolar (20-21) or (20-2-1) substrates are used, the opening areas 103 are oriented in a direction parallel to [−1014] or [10-14], respectively. Other planes of the substrate may be use as well, with the opening areas 103 oriented in other directions.

When using a III-nitride substrate 101, the present invention can obtain high quality III-nitride semiconductor layers 105, 107. As a result, the present invention can also easily obtain devices 110 with reduced defect density, such as reduced dislocation and stacking faults.

Moreover, these techniques can be used with a hetero-substrate, such as sapphire, SiC, LiAlO₂, Si, Ga₂O₃ etc., as long as it enables growth of the ELO GaN-based layers 105 through the growth restrict mask 102.

Growing a Plurality of Epitaxial Layers on the Substrate Using the Growth Restrict Mask

The III-nitride semiconductor device layers 107 are grown on the III-nitride ELO layers 105 in the flat region 108 by conventional methods. In one embodiment, MOCVD is used for the epitaxial growth of the island-like III-nitride semiconductor layers including the III-nitride ELO layers 105 and the III-nitride semiconductor device layers 107. The resulting island-like III-nitride semiconductor layers 105, 107 are separated from each other, because the MOCVD growth is stopped before the III-nitride ELO layers 105 coalesce at 106. In one embodiment, the III-nitride ELO layers 105 are made to coalesce and later etching is performed to remove unwanted regions.

Trimethylgallium (TMGa), trimethylindium (TMIn) and triethylaluminium (TMAl) are used as III elements sources. Ammonia (NH₃) is used as the raw gas to supply nitrogen. Hydrogen (H₂) and nitrogen (N₂) are used as a carrier gas of the III elements sources. It is important to include hydrogen in the carrier gas to obtain a smooth surface epi-layer.

Saline and Bis(cyclopentadienyl)magnesium (Cp₂Mg) are used as n-type and p-type dopants. The pressure setting typically is 50 to 760 Torr. III-nitride-based semiconductor layers are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700.

ELO of Limited Area Epitaxy (LAE) III-Nitride Layers

In the prior art, a number of pyramidal hillocks have been observed on the surface of m-plane III-nitride films following growth. See, for example, US Patent Application Publication No. 2017/0092810. Furthermore, a wavy surface and depressed portions have appeared on the growth surface, which made the surface roughness worse. This is a very severe problem. For example, according to some papers, a smooth surface can be obtained by controlling an off-angle (>1 degree) of the substrate's growth surface, as well as by using an N₂ carrier gas condition. These are very limiting conditions for mass production, however, because of the high production costs. Moreover, GaN substrates have a large fluctuation of off-angles to the origin from their fabrication methods. For example, if the substrate has a large in-plane distribution of off-angles, it has a different surface morphology at these points in the wafer. In this case, the yield is reduced by the large in-plane distribution of the off-angles. Therefore, it is necessary that the technique does not depend on the off-angle in-plane distribution.

The present invention solves these problems as set forth below:
1. The growth area is limited by the area of the growth restrict mask 102 from the edges of the substrate 101.
2. The substrate 101 is a nonpolar or semipolar III-nitride substrate 101 that has off-angle orientations ranging from −16 degrees to +30 degrees from the m-plane towards the c-plane. Alternatively, a hetero-substrate with a III-nitride-based semiconductor layer deposited thereon may be used, wherein the layer has an off-angle orientation ranging from +16 degrees to −30 degrees from the m-plane towards the c-plane.
3. The island-like III-nitride semiconductor layers 105, 107 have a long side that is perpendicular to an a-axis of the III-nitride-based semiconductor crystal.
4. During MOCVD growth, a hydrogen atmosphere can be used.

In this invention, a hydrogen atmosphere can be used during non-polar and semi-polar growth. This condition is preferable because hydrogen can prevent excessive growth at the edge of the open area 103 from occurring in the initial growth phase.

Those results have been obtained by the following growth conditions.

In one embodiment, the growth pressure ranges from 60 to 760 Torr, although the growth pressure preferably ranges from 100 to 300 Torr to obtain a wide width for the island-like III-nitride semiconductor layers; the growth temperature ranges from 900 to 1200° C. degrees; the V/III ratio ranges from 10-30,000; the TMG is from 2-20 sccm; NH₃ ranges from 0.1 to 10 slm; and the carrier gas is only hydrogen gas, or both hydrogen and nitrogen gases. To obtain a smooth surface, the growth conditions of each plane needs to be optimized by conventional methods.

After growing for about 2-8 hours, the III-nitride ELO layers 105 had a thickness of about 1-50 μn and a bar width of about 50-150 μm.

Fabricating the Device

The device 110 is fabricated at the flat surface region 108 by conventional methods, wherein various device 110 designs are possible. For example, μLEDs may be fabricated, if only the front-end process is enough to realize device 110, such as p-pads and n-pads can be fabricated either along the length or width of the wing of the III-nitride ELO layers 105, as shown in FIG. 4A. Preferably, either a vertical configuration, or pads along the length of the wing, are opted to avoid larger growth times.

Forming a Structure for Separating Device Units

The aim of this step is to prepare for isolation from the host substrate 101 for the III-nitride ELO layers 105 and III-nitride device layers 107. By placing a selective etching mask, III-nitride device layers 107 are separated from the host substrate 101 by etching regions 201, 202, at least to expose the growth restrict mask 102.

The dividing may also be performed via scribing by a diamond tipped scriber or laser scriber, for example, tools such as RIE (Reactive Ion Etching) or ICP (Inductively Coupled Plasma); but is not limited to those methods, and other methods may also be used to isolate device units.

To keep the isolated III-nitride device layers 107 on the host substrate 101 while performing a regrowth, an epitaxial bridge 301 is proposed in this invention. It is also possible to ensure that the isolated III-nitride device layers 107 stay on the host substrate 101 by modifying the etching mask. Region 201, which connects the III-nitride ELO layers 105 directly with the host substrate 101, was modified in such a way that a non-epitaxial bridge 303 with the host substrate 101 still remains, even after exposing a growth restrict mask 102 at the region 202, as shown in FIG. 4H and FIG. 5E.

Moreover, the epitaxial bridge 301 can help position the emitting aperture 111 away from the opening area 103, which can reduce the number of defects included within the emitting aperture 111. With the aim of keeping the emitting aperture 111 away from the opening area 103, the bridge 301, 303 can be comprised of any other material such as dielectric layers, metals, semiconductors and insulators. In using a side from the epitaxial bridge 301, the devices 110 can completely separate from the III-nitride layers 105, 107. In other words, the devices 110 are placed on the growth restrict mask 102. At this time, the III-nitride layers 105, 107 on the opening area 103 still remain. In addition, the devices 110 are connected with the III-nitride layers 105, 107 on the opening area 103. By doing this, the devices 110 can be held on the growth restrict mask 102. This makes it possible to make the devices 110 far from opening area 103. This is preferred, because it uses a low defect area for the device 110.

Regrowth of Crystalline Layers with Epitaxial Bridge

This invention follows two approaches with regard to regrowth. In one approach, only a thin p-layer was grown and, in another approach, complete device structure layers were regrown on the isolated wing of the n-type III-nitride ELO layers 105.

These approaches have their own advantages.
(a) Regrowth may heal the plasma damage associated in forming a light emitting structure 404, as regrowth temperatures are generally higher.
(b) Damaged crystalline layers during plasma etching may be exposed to the crystalline environment, thus repairing the damage or healing the etched defects.
(c) When regrowth is only for a p-type layer 107b, active region 107a formation could be uniform, leading to uniform wavelength emission throughout the wafer.
(d) When regrowth is performed for re-growing of entire device layers 107, growth temperatures can be higher, thus leading to reduced crystalline defects.
(e) When regrowth is performed for only the p-type layer 107b, the layer 107b must be very thin, for example, a thin Mg-doped GaN layer 107b with higher doping concentration can be grown using pulsed sputtering deposition.
(f) The epitaxial bridge 301 can be stable at elevated temperatures.
(g) Devices 110 can be plucked from the host substrate 101 by mechanically breaking the epitaxial bridge 301.

ELO III-Nitride Device Layers are Removed from the Substrate

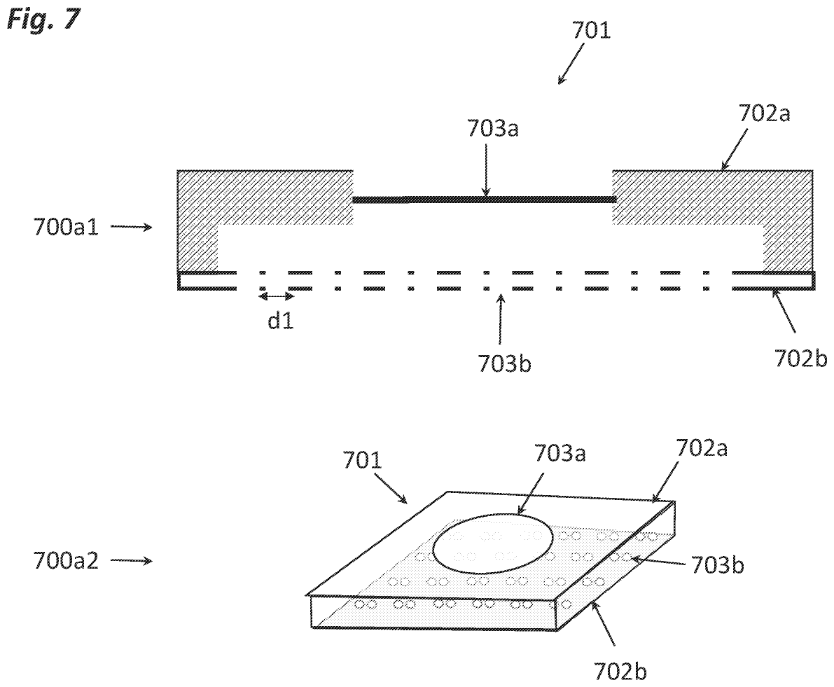

The epitaxial bridge 301 is very delicate, and thus ultrasonic waves or a small impact are enough to break the bridge 301. The completed hanging devices 110 may be transferred from their host substrate 101 using the following methods.
1. Elastomer (PDMS) stamps: As shown in FIG. 4M, PDMS stamps 414 are flexible enough to pick the isolated III-nitride device layers 107 from their host substrate 101. One may also pick selectively in order to transfer the layers onto a target back panel 416, as indicated in FIG. 4M.
2. Vacuum chuck: This invention proposes a new way to pick isolated III-nitride device layers 107 from their host substrate 101. As the III-nitride device layers 107 have a very weak connection at the host substrate 101, it is simple to use a vacuum controlled chuck 701, as shown in schematics 700a1 and 700a2 in FIG. 7, to remove the III-nitride device layers 107, as described in more detail below. In addition, a local repair may be performed on the back panel 416 using a vacuum chuck 701 for selective picking. Alternatively, a PDMS stamp 414 may also be used for selective picking.

Mounting the Device on a Display Panel

The divided/isolated devices 110 are lifted using the approaches described above: (1) PDMS stamp 414 or (2) vacuum chuck 701, and then mounted on a display panel 416.

Using a Vacuum Chuck to Pick ELO III-Nitride Device Layers and Local Repair Methods

This invention provides a solution to the problem of mass transferring of smaller light emitting apertures 111, alternatively called emissive inorganic pixels, when targeted sizes are below 50 μm. μLEDs, fabricated on the wing of the III-nitride ELO layers 105, can be removed as mentioned above. In particular, these devices 110 preferably have larger wing regions of the III-nitride ELO layers 105 and smaller open regions 201, that is, a ratio between the wing regions of the III-nitride ELO layers 105 and open regions 201 should be more than 1, more preferably 5-10, and in particular, open regions 201 should be around 1-5 μm. Therefore, devices 110 can be removed from the III-nitride substrate 101 more easily and can be transferred to external carriers or processed in further steps in an easy manner.

A vacuum chuck 701 is combination of at least two plates 702a, 702b, wherein a top plate 702a has a large vacuum hole 703a and a bottom plate 702b has vacuum holes 703b with dimensions dl slightly smaller than the device 110 to be lifted from the host substrate 101, and, which can be controlled either electrically or magnetically for physically extracting isolated devices 110 out of the host substrate 101.

A vacuum chuck 701 is placed over the isolated devices 110 on the host substrate 101 and the devices 110 are extracted out of the host substrate 101 by turning on a vacuum using a valve.

Then, the device layers contained by the chuck 701 are either placed on a processed carrier plate 704, or directly attached onto a display back panel 416.

### Definitions of Terms

III-Nitride-Based Substrate

The III-nitride-based substrate 101 may comprise any type of III-nitride-based substrate, as long as a III-nitride-based substrate enables growth of III-nitride-based semiconductor layers 105, 107, 108, 109, through a growth restrict mask 102, any GaN substrate 101 that is sliced on a {0001}, {11-22}, {1-100}, {20-21}, {20-2-1}, {10-11}, {10-1-1} plane, etc., or other plane, from a bulk GaN, and AlN crystal substrate.

Hetero-Substrate

Moreover, the present invention can also use a hetero-substrate. For example, a GaN template or other III-nitride-based semiconductor layer may be grown on a hetero-substrate, such as sapphire, Si, GaAs, SiC, Ga₂O₃, etc., prior to the growth restrict mask 102. The GaN template or other III-nitride-based semiconductor layer is typically grown on the hetero-substrate to a thickness of about 2-6 μm, and then the growth restrict mask 102 is disposed on the GaN template or another III-nitride-based semiconductor layer.

Growth Restrict Mask

The growth restrict mask 102 comprises a dielectric layer, such as SiO₂, SiN, SiON, Al₂O₃, AlN, AlON, MgF, ZrO₂, TiN etc., or a refractory metal or precious metal, such as W, Mo, Ta, Nb, Rh, Ir, Ru, Os, Pt, etc. The growth restrict mask 102 may be a laminate structure selected from the above materials. It may also be a multiple-stacking layer structure chosen from the above materials.

In one embodiment, the thickness of the growth restrict mask 102 is about 0.05-3 μm. The width of the growth restrict mask 102 is preferably larger than 20 μm, and more preferably, the width is larger than 40 μm. The growth restrict mask 102 is deposited by sputter, electron beam evaporation, plasma-enhanced chemical vaper deposition (PECVD), ion beam deposition (IBD), etc., but is not limited to those methods.

On an m-plane free standing GaN substrate 101, the growth restrict mask 102 comprises a plurality of opening areas 103, which are arranged in a first direction parallel to the 11-20 direction of the substrate 101 and a second direction parallel to the 0001 direction of the substrate 101, periodically at intervals extending in the second direction. The length of the opening area 103 is, for example, 200 to 35000 μm; the width is, for example, 2 to 180 μm; and the interval of the opening area 103 is, for example, 20 to 180 μm. The width of the opening area 103 is typically constant in the second direction but may be changed in the second direction as necessary.

On a c-plane free standing GaN substrate 101, the opening areas 103 are arranged in a first direction parallel to the 11-20 direction of the substrate 101 and a second direction parallel to the 1-100 direction of the substrate 101.

On a semipolar (20-21) or (20-2-1) GaN substrate 101, the opening areas 103 are arranged in a direction parallel to [−1014] and [10-14], respectively.

Alternatively, a hetero-substrate 101 can be used. When a c-plane GaN template is grown on a c-plane sapphire substrate 101, the opening area 103 is in the same direction as the c-plane free-standing GaN substrate 101; when an m-plane GaN template is grown on an m-plane sapphire substrate 101, the opening area 103 is same direction as the m-plane free-standing GaN substrate 101. By doing this, an m-plane cleaving plane can be used for dividing the bar of the device 110 with the c-plane GaN template, and a c-plane cleaving plane can be used for dividing the bar of the device 110 with the m-plane GaN template; which is much preferable.

III-Nitride-Based Semiconductor Layers

The III-nitride ELO layers 105 and the III-nitride device layers 107 can include In, Al and/or B, as well as other impurities, such as Mg, Si, Zn, 0, C, H, etc.

The III-nitride-based device layers 107 generally comprise more than two layers, including at least one layer among an n-type layer, an undoped layer and a p-type layer. The III-nitride-based device layers 107 may comprise a GaN layer, an AlGaN layer, an AlGaInN layer, an InGaN layer, etc. In the case where the device 110 has a plurality of III-nitride-based semiconductor layers 105, 107, the distance between the island-like III-nitride semiconductor layers 105, 107 adjacent to each other is generally 30 μm or less, and preferably 10 μm or less, but is not limited to these figures. In the semiconductor device 110, a number of electrodes according to the types of the semiconductor device 110 are disposed at predetermined positions.

Separation Length

The separation length L is formed using either an epitaxial bridge 301 or a non-epitaxial bridge 303. The separation length L keeps the light emitting aperture 111 away from the open region 201 of the III-nitride ELO layers 105. The length L is designed to be at least 1 μm to avoid any edge damage, crystal defects near the open region 201, etc. A longer length guarantees an easy breakoff of devices 110 when pressed with a PDMS stamp 414 or vacuum chuck 701, and a better crystal quality for the light emitting aperture 111. In the case of the epitaxial bridge 301, devices 110 may use a cleavable plane in the length L to separate the devices 110 from the host substrate 101.

Merits of Epitaxial Lateral Overgrowth

The crystallinity of the island-like III-nitride semiconductor layers 105, 107 grown using the III-nitride ELO layers 105 upon the growth restrict mask 102 from a striped opening area 103 of the growth restrict mask 102 is very high.

Furthermore, two advantages may be obtained using a III-nitride-based substrate 101. One advantage is that a high-quality III-nitride semiconductor layer 107 can be obtained on the wings of the III-nitride ELO layers 105, such as with a very low defects density, as compared to using a sapphire substrate 101.

The use of a hetero-substrate 101, such as sapphire (m-plane, c-plane), LiAlO₂, SiC, Si, etc., for the growth of the epilayers 105, 107 is that these substrates 101 are low-cost substrates. This is an important advantage for mass production.

When it comes to the quality of the device 110, the use of a free standing III-nitride-based substrate 101 is more preferable, due to the above reasons. On the other hand, the use of a hetero-substrate 101 makes it cheaper and scalable.

Also, as the growth restrict mask 102 and the III-nitride ELO layers 105 are not bonded chemically, the stress in the III-nitride ELO layers 105 can be relaxed by a slide caused at the interface between the growth restrict mask 102 and the III-nitride ELO layers 105.

Flat Surface Region

The flat surface region 108 is between layer bending regions 109. Furthermore, the flat surface region 108 is in the region of the growth restrict mask 102.

Fabrication of the semiconductor device 110 is mainly performed on the flat surface region 108. The width of the flat surface region 108 is preferably at least 5 μm, and more preferably is 10 μm or more. The flat surface region 108 has a high uniformity of thickness for each of the semiconductor layers.

Layer Bending Region

FIG. 2C illustrate the layer bending regions 109. If the layer bending region 109 that includes the active layer 107a remains in the device 110, a portion of the emitted light from the active layer 107a is reabsorbed. As a result, it is preferable to remove at least a part of the active layer 107a in the layer bending region 109 by etching.

From another point of view, an epitaxial layer of the flat surface region 108 except for the opening area 103 has a lesser defect density than an epitaxial layer of the opening area 103. Therefore, it is more preferable that the apertures 111 should be formed in the flat surface region 108 including on a wing region.

Semiconductor Device

The semiconductor device 110 is, for example, a Schottky diode, a light-emitting diode, a semiconductor laser, a photodiode, a transistor, etc., but is not limited to these devices. This invention is particularly useful for micro-LEDs. This invention is especially useful for a semiconductor laser which require smooth regions for cavity formation.

Epitaxial Bridge

An epitaxial bridge 301 grown using ELO is specially constructed to hold the III-nitride ELO and device layers 105, 107 at regrowth of crystal layer environment. Examples of such a structure are shown in FIG. 3, FIG. 4F and FIG. 5C.

### Alternative Embodiments

The following describes alternative embodiments of the present invention.

### First Embodiment

A first embodiment discloses a method for manufacturing a III-nitride-based micro-display 416 containing semiconductor devices 110.

In the first embodiment, as shown in FIG. 1, a base substrate or a host substrate 101 is first provided, and a growth restrict mask 102 that has a plurality of striped opening areas 103 is formed on the substrate 101.

In this embodiment, the island-like III-nitride ELO layers 105 are allowed contact neighboring layers 105 in order to form a foundation layer for the desired device 110. Thereafter, device layers 107, such as multi quantum well structures, waveguides, electron blocking layer, p-GaN, etc., were grown on the above the III-nitride ELO layers 105. Devices 110, as described in FIGS. 4 and 5, such as μLEDs, are fabricated on the wing regions of the III-nitride ELO layers 105. A regrowth area 408 is opened on the device layers 107 and then the III-nitride ELO layers 105 and device layers 107 are divided into individual devices 110 or groups of devices 110 by etching all the way down to expose the underlying growth restrict mask 102 via removing regions 201, 202. While etching regions 201, 202, an epitaxial bridge 301 is formed near region 201, as shown in FIG. 3. At this stage, the III-nitride ELO layers 105 and device layers 107 literally have only the epitaxial bridge 301 as a connection to the host substrate 101, which keeps the III-nitride ELO layers 105 and device layers 107 from separating from the substrate 101 until desired.

The structure containing the epitaxial bridge 301 and the regrowth area 408 with the protection layer 407 is sent to a regrowth chamber for forming a thin highly doped p-GaN layer 409. The regrowth may help to heal the damage caused by the etching in the plasma environment.

Since the device layers 107 have already formed below the regrowth area 408, it is recommended to not use an aggressive temperature growth environment to form a p-GaN layer 409. For example, pulsed sputter deposition (PSD), pulsed laser deposition, or MBE, may be used to grow a high concentration Mg-doped p-GaN layers 409. These regrowth layers may help to obtain improved current spreading in the p-GaN layer 409 and heal the device damage that may have occurred in the plasma etching.

Once the regrowth finished, the growth restrict mask 102 and protection layer 407 are etched using BHF or HF, leaving only the epitaxial layers 105, 107, as indicated in FIG. 4F.

A TCO layer 410 is laid over a light emitting area and annular p-pads and n-pads 411 are deposited, as shown in FIG. 4I.

Then, the weakly attached III-nitride ELO layers 105 and device layers 107 are transferred onto a desired carrier, such as a display panel 416, using tools such as an elastomer stamp 414, vacuum chuck 701, etc. The display panels 416 can be used in a number of applications, such as TVs, laptops, phones, AR/VR/MR headsets, HUDs, etc.

### Second Embodiment

A second embodiment discloses a III-nitride-based micro-display 416 containing semiconductor devices 110.

In the first embodiment, as shown in FIG. 1, a base substrate or a host substrate 101 is first provided, and a growth restrict mask 102 that has a plurality of striped opening areas 103 is formed on the substrate 101.

In the second embodiment, the island-like III-nitride ELO layers 105 are allowed contact neighboring layers 105 in order to form foundation or base layers for the desired device 110. These base III-nitride ELO layers 105 are n-GaN layers. In this embodiment, device layers 107, such as multi quantum well structures, waveguides, electron blocking layer, p-GaN, etc., were grown on or above the base III-nitride ELO layers 105 in the regrowth process.

A regrowth area 408 is opened on the base n-GaN layers 105, and then the III-nitride ELO layers 105 and device layers 107 are divided into individual devices 110 or groups of devices 110 by etching to expose the underlying growth restrict mask 102 via removing regions 201, 202. While etching regions 201, 202, a epitaxial bridge 301 is formed near region 201, as shown in FIG. 3. At this stage, the III-nitride ELO layers 105 and device layers 107 literally have only the epitaxial bridge 301 as a connection to the host substrate 101, which keeps the III-nitride ELO layers 105 and device layers 107 from separating from the host substrate 101 until desired. The resulting pattern is shown in FIG. 5E.

The structure containing the epitaxial bridge 301 and regrowth area 408 with the protection layer 407 is sent to a regrowth chamber for regrowing device layers 107, such as n-GaN layers, multi quantum well structures, waveguides, electron blocking layers, p-GaN layers, etc. The regrowth may help to heal the damage caused by the etching in the plasma environment.

Since, in this process, the regrowth comprises growing an active region 107a, one may use higher temperatures than the process described in the first embodiment. Growing at higher temperatures increases the crystalline quality of the layers 107, thereby improved performance of the devices 110 can be observed.

For example, MOCVD or MBE may be used for the regrowth. These regrowth layers 107 may help to heal the device 110 damage that may have occurred in the plasma etching.

Once the regrowth is finished, the growth restrict mask 102 and protection layer 407 are etched using a BHF or HF, leaving only the epitaxial layers 105, 107, as indicated in FIG. 5I. One may choose to leave the protection layer 407 by placing a TCO layer 410 before removing the growth restrict mask 102. The resulting bridge 301 structure of this approach is shown in FIG. 5I.

Then, weakly-attached III-nitride ELO layers 105 and device layers 107 are transferred onto a desired carrier, which can be a display panel 416, using tools such as an elastomer stamp 414, vacuum chuck 701, etc. The display panels 416 can be used in a number of applications, such as TVs, laptops, phones, AR/VR/MR headsets, HUDs, etc.

### Third Embodiment

A third embodiment provides a structure for electrical injection. In the first and second embodiments, electrical injection is chosen as a later injection. However, the backside interface 601 of the III-nitride ELO layers 105 may be used as one of the electrical injection pads, which leads to a vertical configuration of electrical injection, as indicated in FIG. 6.

### Fourth Embodiment

A fourth embodiment describes on how to remove isolated devices 110 from their host substrate 101 using a PDMS stamp 414. As the isolated III-nitride ELO layers 105 have only the epitaxial bridge 301 as a connection with the host substrate 101, this connection can be easily broken using movement of the PDMS stamp 414. As described in FIG. 4M, a PDMS stamp 414 can be designed either to pick all of the isolated III-nitride ELO layers 105 and device layers 107 together or even to selectively pick only some of the isolated III-nitride ELO layers 105 and device layers 107.

### Fifth Embodiment

A fifth embodiment picks the isolated III-nitride ELO layers 105 and device layers 107 from the host substrate 101 using a vacuum chuck 701, wherein the vacuum chuck 701 is designed to contain at least two plates 702a, 702b. The plate 702b contains finite dimension holes 703b, which are smaller than the dimensions of the devices 110. The plate 702a has a larger dimension hole 703a, in order to control the holding process of the plate 702b. The vacuum hole 703a may be controlled either by a mechanical method, an electromagnetic method, or a hydraulic method.

One may also use the vacuum chuck 701 to pick up only selected devices 110 by closing undesired vacuum holes 703b on the plate 702b, as shown in FIG. 7.

### Sixth Embodiment

In a sixth embodiment, AlGaN layers are used as the island-like III-nitride ELO layers 105 and III-nitride device layers 107, which may be grown on various off angle substrates 101. The AlGaN layers can have a very smooth surface, and can be removed, as the island-like III-nitride ELO layers 105 and device layers 107, from various off-angle substrates 101.

In this case, an active laser, which emits UV-light (UV-A or UV-B or UV-C), can be grown on the AlGaN ELO layers 105. After removal, the AlGaN ELO layers 105 with an active layer 107a looks like a UV device 110 with a pseudo-AlGaN substrate 101. By doing this, one can obtain a high-quality UV-LED display panel 416. Applications of this may lead to sterilization, lighting, etc.

### Seventh Embodiment

In a seventh embodiment, a III-nitride ELO layer 105 is grown on various off-angle substrates 101. The off-angle orientations range from 0 to +15 degrees and 0 to −28 degrees from the m-plane towards the c-plane. The present invention can remove the bar of the device 110 from the various off-angle substrates 101. This is a big advantage for this technique, as various off-angle orientations semiconductor plane devices 110 can be realized without changing the fabrication process.

### Eighth Embodiment

In an eighth embodiment, a III-nitride ELO layer 105 is grown on c-plane substrates 101 with two different mis-cut orientations. Then, the III-nitride ELO and device layers 105, 107 are removed after processing a desired device 110 using the invention described in this application.

### Ninth Embodiment

In a ninth embodiment, a sapphire substrate 101 with a buffer layer is used as the hetero-substrate. The resulting structure is almost the same as the first and second embodiments, except for using the sapphire substrate 101 and a buffer layer. In this embodiment, the buffer layer may also include an additional n-GaN layer or undoped GaN layer. The buffer layer is grown at a low temperature of about 500-700° C. degrees. The n-GaN layer or undoped GaN layer is grown at a higher temperature of about 900-1200° C. degrees. The total thickness is about 1-3 μm. Then, the growth restrict mask 102 is disposed on the buffer layer and the n-GaN layer or undoped GaN layer.

On the other hand, it is not necessary to use the buffer layer. For example, the growth restrict mask 102 can be disposed on the hetero-substrate 101 directly. After that, the III-nitride ELO layer 105 and/or III-nitride device layers 107 can be grown.

### Tenth Embodiment

A tenth embodiment is about a non-epitaxial bridge 303. The processes mentioned in the first and second embodiments may also be realized without using an epitaxial bridge 301. Regions 201, 202 separate the device layers 107 and isolates the devices 110 from the host substrate 101, as shown in FIG. 3B. Then, a non-epitaxial bridge 303 is placed over the device layers 107 before reintroducing the device layers 107 into a crystalline growth chamber. The non-epitaxial bridge 303 material can be as similar to the growth restrict mask 102 or a material different from the growth restrict mask 102. The main function of the non-epitaxial bridge 303 is to keep the devices 110 on the growth restrict mask 102 when introduced into a crystalline regrowth chamber. Also, a separation length L of the bridge 303 allows one to design light emitting apertures 111 completely on the wing regions of the III-nitride ELO layers 105. The separation length L can be measured similar to the epitaxial bridge 301 case in order to avoid crystal defects from region 201. At least 1 μm must be left between region 201 and the edge of the device 110.

Like the epitaxial bridge 301 case, only a p-type layer 409 regrowth as described in the first embodiment, or a complete device layer 107 growth as described in the second embodiment, can be performed, even with the non-epitaxial bridge 303, as shown in FIG. 3B.

Process Steps

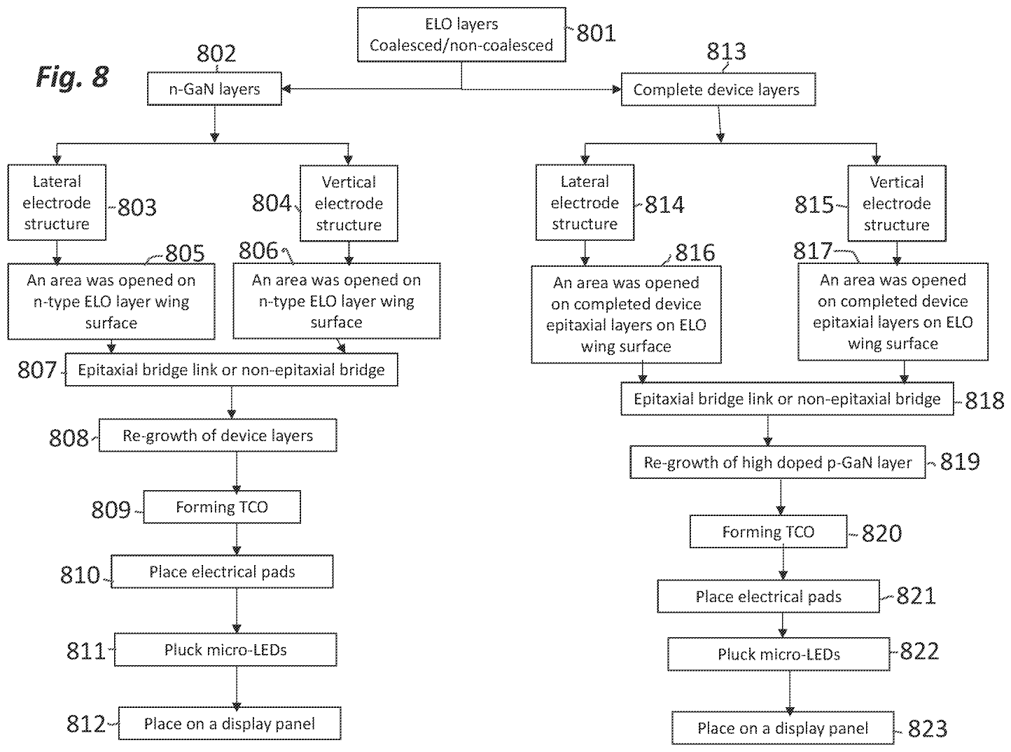

FIG. 8 is a flowchart illustrating how to fabricate semiconducting devices according to this invention.

Block 801 represents the step of forming the III-nitride ELO layers 105, which may coalesced or non-coalesced.

Block 802 represents the step of where the III-nitride ELO layers 105 comprise only n-GaN layers.

Block 803 represents the step of forming a lateral electrode structure and Block 804 represents the step of forming a vertical electrode structure.

Blocks 805 and 806 both represent the step of opening an area on the surface of the wing region of the III-nitride ELO layers 105.

Block 807 represents the step of forming the epitaxial or non-epitaxial bridge 301, 303.

Block 808 represents the step of performing a regrowth of the device layers 107.

Block 809 represents the step of forming the TCO layers 410 on the device layers 107.

Block 810 represents the step of placing electrical pads 411 on the resulting device 110.

Block 811 represents the step of plucking the devices 110 from the substrate 101, after breaking the connection with the substrate 101 comprised of the epitaxial or non-epitaxial bridge 301, 303.

Block 812 represents the step of placing the devices 110 on the display panel 416, or another carrier or submount.

Block 813 represents the step of forming the III-nitride device layers 107 on the III-nitride ELO layers 105.

Block 814 represents the step of forming a lateral electrode structure and Block 815 represents the step of forming a vertical electrode structure.

Blocks 816 and 817 both represent the step of opening an area on the surface of the device layers 107 on the wing region of the III-nitride ELO layers 105.

Block 818 represents the step of forming the epitaxial or non-epitaxial bridge 301, 303.

Block 819 represents the step of performing a regrowth of a highly-doped p-GaN layer 409.

Block 820 represents the step of forming the TCO layer 410 on the device layers 107.

Block 821 represents the step of placing electrical pads 411 on the resulting device 110.

Block 822 represents the step of plucking the devices 110 from the substrate 101, after breaking the connection with the substrate 101 comprised of the epitaxial or non-epitaxial bridge 301, 303.

Block 823 represents the step of placing the devices 110 on the display panel 416, or another carrier or submount.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A method of preparing a device, comprising:
providing island-like semiconductor layers comprising:
one or more epitaxial lateral overgrowth (ELO) layers and device layers on a substrate; and
a connecting link between the substrate and the ELO layers; and
transferring the ELO layers and device layers to a submount by breaking the connecting link.

2. The method of claim 23, further comprising performing device fabrication before breaking the connecting link.

3. The method of claim 1, wherein the connecting link is an epitaxial bridge.

4. The method of claim 1, wherein the connecting link is a non-epitaxial bridge.

5. The method of claim 1, wherein the connecting link comprises a separation length between a light emitting aperture on the wing region of the ELO layers and an open area of the ELO layers.

6. The method of claim 5, wherein the separation length at least partially stays on the wing region of the ELO layers.

7. The method of claim 1, wherein the breaking includes fracturing and/or cleaving of the connecting link.

8. (canceled)

9. The method of claim 1, wherein the connecting link holds the ELO layers and device layers on the substrate.

10. The method of claim 1, wherein the transferring integrates the ELO layers and device layers onto a larger wafer.

11. The method of claim 2, wherein the fabricating is performed after the transferring.

12. The method of claim 1, wherein the transferring is performed using a pick-and-place method.

13. The method of claim 1, wherein the transferring is performed selectively.

14. (canceled)

15. The method of claim 1, wherein the substrate is independent of crystal orientations.

16. (canceled)

17. A method of preparing a device, comprising:
providing island-like semiconductor layers comprising:
one or more epitaxial lateral overgrowth (ELO) layers on a substrate; and
a connecting link between the substrate and the ELO layers;
performing a regrowth of one or more device layers on the ELO layers; and
transferring the device layers to a submount by breaking the connecting link.

18. The method of claim 17, further comprising fabricating a light emitting aperture on a wing region of the ELO layers and device layers.

19. The method of claim 18, further comprising performing device fabrication before breaking the connecting link.

20. The method of claim 18, wherein the fabricating is performed after the transferring.

21. A device, comprising:
a substrate; and
one or more epitaxial lateral overgrowth (ELO) layers and device layers on the substrate; and
a connection link between the substrate and the ELO layers.

22. The device of claim 21, further comprising a light emitting aperture on a wing region of the ELO layers and device layers.

23. The method of claim 1, further comprising fabricating a light emitting aperture on a wing region of the ELO layers and device layers.

24. The method of claim 2, the submount has an embedded electrode track pad.
